(19) United States
(12) Patent Application Publication
(10) Pub. No.: US 2014/0061970 A1
(43) Pub. Date: Mar. 6, 2014

(54) NANOIMPRINT CURABLE COMPOSITION, NANOIMPRINT-LITHOGRAPHIC MOLDED PRODUCT, AND METHOD FOR FORMING PATTERN

(71) Applicants: Hitoshi Sekine, Sakura-shi (JP); Yasuhiro Takada, Sakura-shi (JP); Hisashi Tanimoto, Sakura-shi (JP); Naoto Yagi, Sakura-shi (JP)

(72) Inventors: Hitoshi Sekine, Sakura-shi (JP); Yasuhiro Takada, Sakura-shi (JP); Hisashi Tanimoto, Sakura-shi (JP); Naoto Yagi, Sakura-shi (JP)

(73) Assignee: DIC CORPORATION, Tokyo (JP)

(21) Appl. No.: 13/985,792

(22) PCT Filed: Feb. 14, 2012
(86) PCT No.: PCT/JP2012/053373

§ 371 Date: Nov. 19, 2013

(30) Foreign Application Priority Data
Feb. 15, 2011 (JP) 2011-029654
Jul. 29, 2011 (JP) 2011-166787
Aug. 2, 2011 (JP) 2011-169221

(51) Int. Cl. G03F 7/075; G03F 7/00

(52) U.S. Cl. CPC G03F 7/0757; G03F 7/0002
USPC 264/293; 524/588

(57) ABSTRACT

The present invention provides a nanoimprint curable composition to be used in “nanoimprint lithography” in which a nanoimprint mold is pressed to transfer a fine concave-convex pattern, the nanoimprint curable composition containing a composite resin which has a polysiloxane segment and a polymer segment other than the polysiloxane segment, the polysiloxane segment containing a silanol group and/or hydrolyzable silyl group and having a polymerizable double bond. In addition, the present invention provides a nanoimprint-lithographic molded product, resist film, resin mold, and method for forming a pattern, which each involves use of the nanoimprint composition.

### TECHNICAL FIELD

The present invention relates to a curable composition used in “nanoimprint lithography” in which a nanoimprint mold having a fine concave-convex pattern is pressed to transfer the pattern. The present invention also relates to a nanoimprint-lithographic molded product, resist film, resin mold, and method for forming a pattern which each involve use of the curable composition.

### BACKGROUND ART

It is known that photosensitive compositions and dry-film resist materials containing the photosensitive compositions have been typically used as resist materials, such as solder resists, etching resists, and plating resists, used for forming conductive circuits or machining electrodes on substrates in the field of, for example, printed wiring boards, liquid crystal display devices, plasma displays, large-scale integrated circuits, thin transistors, semiconductor packages, color filters, and organic electroluminescent devices or used for precisely processing metal. In recent years, as the weight, thickness, and size of these devices have been reduced, a need for forming fine patterns has been increased in printed wiring boards, lead frames, and packages, such as BGA and CSP, used therein.

Patterns have been typically formed by photolithography or laser drawing. In photolithography, resolution depends on the wavelength of light; for example, it is difficult to form a fine structure having a dimension of not more than 100 nm. On the other hand, laser drawing enables formation of a structure having a dimension of not more than 100 nm; however, another problem of insufficient throughput arises.

Nowadays, nanoimprint lithography has been studied to enhance throughput. In the nanoimprint lithography, a nanoimprint master mold having a specific fine concave-convex pattern preliminarily formed by, for instance, electron beam lithography is pressed against a substrate to which a nanoimprint resin has been applied, thereby transferring the concave-convex pattern of the nanoimprint master mold to the nanoimprint resin on the substrate. The time taken to carry out a single process for, e.g., an area of one square inch or more is significantly shorter as compared with laser drawing. These days, a resin composition suitable for such nanoimprint lithography has been proposed (for instance, see Patent Literature 1).

In view of a need for forming a fine concave-convex pattern, there have been requirements for a composition suitably used in nanoimprint lithography, such as excellent pattern formability; good pattern-shape-holding properties after a residual film is removed from a cured pattern, namely, nanoimprint-lithographic cured product; mold release properties; and the good transparency, thermal resistance, light fastness, water resistance, solvent resistance, and acid resistance of a nanoimprint-lithographic cured product.

### CITATION LIST

### Patent Literature

PTL 1: Japanese Unexamined Patent Application Publication No. 2011-766

### SUMMARY OF INVENTION

### Technical Problem

It is an object of the present invention to provide a nanoimprint curable composition which exhibits good pattern formability and pattern-holding properties and which can be used in nanoimprint lithography. It is another object of the present invention to provide a nanoimprint-lithographic molded product made of such a nanoimprint curable composition.

It is another object of the present invention to provide a resist film which exhibits excellent etching resistance and which is the nanoimprint-lithographic molded product and to provide a patterned product which can be produced by etching with the resist film.

It is another object of the present invention to provide a resin mold that is the nanoimprint-lithographic molded product and to provide a replica mold produced with the resin mold, the resin mold enabling transfer of a fine pattern in a nano-order size and exhibiting an excellent release property.

### Solution to Problem

The inventors have intensively carried out studies and found that a nanoimprint curable composition which contains a composite resin having a polysiloxane segment that contains a silanol group and/or hydrolyzable silyl group and a polymerizable double bond and having a polymer segment other than the polysiloxane particularly exhibits excellent pattern formability and pattern-shape-holding properties, thereby accomplishing the above-mentioned objects.

In particular, an aspect of the present invention provides a nanoimprint curable composition containing a composite resin (A) and a photopolymerization initiator, the composite resin (A) having a polysiloxane segment (a1) and a vinyl polymer segment (a2), the polysiloxane segment (a1) containing a structural unit represented by Formula (1) and/or Formula (2) and a silanol group and/or hydrolyzable silyl group, the polysiloxane segment (a1) and the vinyl polymer segment (a2) being linked to each other through a bond represented by Formula (3)

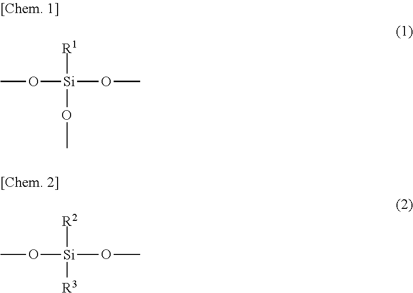

(where R¹, R², and R³ each independently represent a group having a polymerizable double bond which is selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms); an alkyl group having 1 to 6 carbon atoms; d cycloalkyl group having 3 to 8 carbon atoms; an aryl group; or an aralkyl group having 7 to 12 carbon atoms, wherein at least one of R¹, R², and R³ is the group having a polymerizable double bond)

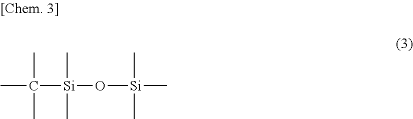

(where the carbon atom constitutes part of the vinyl polymer segment (a2), and the silicon atom bonded to the oxygen atom alone constitutes part of the polysiloxane segment (a1)).

Another aspect of the present invention provides a nanoimprint-lithographic molded product formed through curing the above-mentioned nanoimprint curable composition.

Another aspect of the present invention provides a nanoimprint-lithographic laminate including the above-mentioned nanoimprint-lithographic molded product formed on a substrate.

According to another aspect of the present invention, the above-mentioned nanoimprint-lithographic molded product is a resist film.

According to another aspect of the present invention, the above-mentioned nanoimprint-lithographic molded product is a resin mold.

Another aspect of the present invention provides a replica mold formed with the above-mentioned resin mold.

Another aspect of the present invention provides a method for forming a pattern, the method including applying the above-mentioned nanoimprint curable composition to a substrate to form a film; irradiating the nanoimprint curable composition with an active energy ray for curing in a state in which a master mold having a concave-convex structure is pressed against the nanoimprint curable composition; and removing the mold.

Another aspect of the present invention provides a method for forming a pattern, the method including dry-etching a substrate through a mask to form a pattern on the substrate, the mask being a pattern formed in the resist film included in the above-mentioned nanoimprint-lithographic laminate.

Another aspect of the present invention provides a method for forming a pattern, the method including wet-etching a substrate through a mask to form a pattern on the substrate, the mask being a pattern formed in the resist film included in the above-mentioned nanoimprint-lithographic laminate.

Another aspect of the present invention provides a method for forming a metal mold, the method including (1) forming a coating film of the above-mentioned nanoimprint curable composition, (2) pressing a master mold against the coating film and irradiating the coating film with an active energy ray for curing to form a resin mold that is a nanoimprint-lithographic molded product, (3) forming a metal layer on the resin mold, and (4) removing the resin mold from the metal layer to yield a metal mold.

Another aspect of the present invention provides a method for forming a resin molded product, the method including (1) forming a coating film of the above-mentioned nanoimprint curable composition, (2) pressing a master mold against the coating film and irradiating the coating film with an active energy ray for curing to form a resin mold that is a nanoimprint-lithographic molded product, (5) forming a second resin layer on the resin mold and curing the second resin layer, and (6) removing the resin mold from the second resin layer to yield a resin molded product.

### Advantageous Effects of Invention

An aspect of the present invention can provide a nanoimprint curable composition which can be used in nanoimprint lithography and which enables production of a nanoimprint-lithographic molded product exhibiting excellent pattern formability and pattern-shape-holding properties.

Another aspect of the present invention can provide a resist film, which is the nanoimprint-lithographic molded product, and a nanoimprint-lithographic laminate, the resist film and nanoimprint-lithographic laminate exhibiting excellent etching resistance and enabling good reproduction of a fine pattern on a substrate by etching.

Another aspect of the present invention can provide a resin mold and a replica mold produced with the resin mold, the resin mold being the nanoimprint-lithographic molded product, enabling transfer of a pattern even in a nano-order size, and being well removed from a master mold and the replica mold.

### DESCRIPTION OF EMBODIMENTS

(Composite Resin (A))

A composite resin (A) used in the present invention is a composite resin (A) in which a polysiloxane segment (a1) having a structural unit represented by Formula (1) and/or Formula (2) and containing a silanol group and/or hydrolyzable silyl group (hereinafter simply referred to as “polysiloxane segment (a1)”) is linked to a vinyl polymer segment (a2) containing an alcoholic hydroxyl group (hereinafter simply referred to as “vinyl polymer segment (a2)”) through a bond represented by Formula (3).

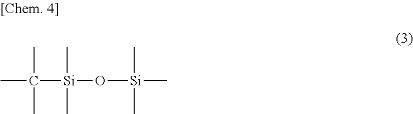

The silanol group and/or hydrolyzable silyl group of the polysiloxane segment (a1) that will be described later is subjected to a dehydration condensation reaction with the silanol group and/or hydrolyzable, silyl group of the vinyl polymer segment (a2) that will be described later, thereby generating the bond represented by Formula (3). Hence, in Formula (3), the carbon atom constitutes part of the vinyl polymer segment (a2), and the silicon atom bonded to the oxygen atom alone constitutes part of the polysiloxane segment (a1).

Examples of the structure of the composite resin (A) include a composite resin having a graft structure in which the polysiloxane segment (a1) is chemically bonded to the polymer segment (a2) to serve as a side chain and a composite resin having a block structure in which the polymer segment (a2) and the polysiloxane segment (a1) are chemically bonded to each other.

Polysiloxane Segment (a1)

The polysiloxane segment (a1) in the present invention is a segment having a structural unit represented by Formula (1) and/or Formula (2) and containing a silanol group and/or hydrolyzable silyl group. The structural unit represented by Formula (1) and/or Formula (2) contains a group having a polymerizable double bond.

(Structural Unit Represented by Formula (1) and/or Formula (2))

The structural unit represented by Formula (1) and/or Formula (2) contains a group having a polymerizable double bond as an essential component. In particular, R¹, R², and R³ in Formulae (1) and (2) each independently represent a group having a single polymerizable double bond, which is selected from the group consisting of —R⁴—CH═CH₂, —R⁴—C(CH₃)═CH₂, —R⁴—O—CO—C(CH₃)═CH₂, and —R⁴—O—CO—CH═CH₂ (where R⁴ represents a single bond or an alkylene group having 1 to 6 carbon atoms); an alkyl group having 1 to 6 carbon atoms; a cycloalkyl group having 3 to 8 carbon atoms; an aryl group; or an aralkyl group having 7 to 12 carbon atoms, wherein at least one of R¹, R², and R³ is the group having a polymerizable double bond. Examples of the alkylene group having 1 to 6 carbon atoms in R⁴ include a methylene group, an ethylene group, a propylene group, an isopropylene group, a butylene group, an isobutylene group, a sec-butylene group, a tert-butylene group, a pentylene group, an isopentylene group, a neopentylene group, a tert-pentylene group, a 1-methylbutylene group, a 2-methylbutylene group, a 1,2-dimethylpropylene group, a 1-ethylpropylene group, a hexylene group, an isohexylene group, a 1-methylpentylene group, a 2-methylpentylene group, a 3-methylpentylene group, a 1,1-dimethylbutylene group, a 1,2-dimethylbutylene group, a 2,2-dimethylbutylene group, a 1-ethylbutylene group, a 1,1,2-trimethylpropylene group, a 1,2,2-trimethylpropylene group, a 1-ethyl-2-methylpropylene group, and a 1-ethyl-1-methylpropylene group. Among these, R⁴ preferably represents a single bond or an alkylene group having 2 to 4 carbon atoms in view of the availability of the raw materials.

Examples of the alkyl group having 1 to 6 carbon atoms include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group. Examples of the cycloalkyl group having 3 to 8 carbon atoms include a cyclopropyl group, a cyclobutyl group, a cyclopentyl group, and a cyclohexyl group. Examples of the aryl group include a phenyl group, a naphthyl group, a 2-methylphenyl group, a 3-methylphenyl group, a 4-methylphenyl group, a 4-vinylphenyl group, and a 3-isopropylphenyl group. Examples of the aralkyl group having 7 to 12 carbon atoms include a benzyl group, a diphenylmethyl group, and a naphthylmethyl group.

The phrase “at least one of R¹, R², and R³ is the group having a polymerizable double bond” refers to the following specific cases: in the case where the polysiloxane segment (a1) has a structural unit represented by Formula (1) alone, R¹ is the group having a polymerizable double bond; in the case where the polysiloxane segment (a1) has a structural unit represented by Formula (2) alone, R² and/or R³ is the group having a polymerizable double bond; and in the case where the polysiloxane segment (a1) has both types of structural units represented by Formulae (1) and (2), at least one of R¹, R², and R³ is the group having a polymerizable double bond.

In the present invention, the number of the polymerizable double bonds contained in the polysiloxane segment (a1) is preferably 2 or more, more preferably 3 to 200, and further preferably 3 to 50, which enables production of a nanoimprint curable composition exhibiting good pattern formability and pattern-holding properties. In particular, at 3 to 20 weight % of the polymerizable double bond content in the polysiloxane segment (a1), desired pattern formability and pattern-holding properties can be obtained. The term “polymerizable double bond” herein collectively refers to a group which is selected from vinyl groups, vinylidene groups, and vinylene groups and which can be subjected to a propagation reaction with free radicals. The polymerizable double bond content refers to the weight % of such vinyl groups, vinylidene groups, or vinylene groups contained in the polysiloxane segment.

Any known functional group containing such vinyl groups, vinylidene groups, or vinylene groups can be used as the group having a polymerizable double bond; in particular, a (meth)acryloyl group represented by —R⁴—C(CH₃)═CH₂ or —R⁴—O—CO—C(CH₃)═CH₂ exhibits good reactivity in ultraviolet curing and good compatibility with the vinyl polymer segment (a2) which will be described later.

The structural unit represented by Formula (1) and/or Formula (2) is a polysiloxane structural unit in which two or three bonds of the silicon serve for crosslinking and which is in the form of a three-dimensional network. Although such a three dimensional network is formed, the network does not have a dense structure. Hence, no gelation will occur during the production process, and good storage stability is enabled.

(Silanol Group and/or Hydrolyzable Silyl Group)

In the present invention, the silanol group refers to a silicon-containing group which has a hydroxyl group directly bonded to the silicon atom. In particular, the silanol group is preferably a silanol group generated by bonding of a hydrogen atom to an oxygen atom having bonds in the structural unit represented by Formula (1) and/or Formula (2).

In the present invention, the hydrolyzable silyl group refers to a silicon-containing group which has a hydrolyzable group directly bonded to the silicon atom. In particular, an example thereof is a group represented by Formula (4).

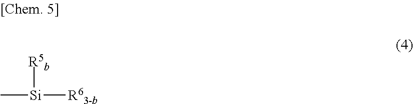

(In Formula (4), R⁵ represents a monovalent organic group such as an alkyl group, an aryl group, or an aralkyl group, and R⁶ represents a hydrolyzable group selected from the group consisting of a halogen atom, an alkoxy group, an acyloxy group, a phenoxy group, an aryloxy group, a mercapto group, an amino group, an amide group, an aminooxy group, an iminooxy group, and an alkenyloxy group. The symbol b represents an integer from 0 to 2).

In R⁵, Examples of the alkyl group include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group. Examples of the aryl group include a phenyl group, a naphthyl group, a 2-methylphenyl group, a 3-methylphenyl group, a 4-methylphenyl group, a 4-vinylphenyl group, and a 3-isopropylphenyl group. Examples of the aralkyl group include a benzyl group, a diphenylmethyl group, and a naphthylmethyl group.

In R⁶, examples of the halogen atom include a fluorine atom, a chlorine atom, a bromine atom, and an iodine atom. Examples of the alkoxy group include a methoxy group, an ethoxy group, a propoxy group, an isopropoxy group, a butoxy group, a sec-butoxy group, and a tert-butoxy group. Examples of the acyloxy group include formyloxy, acetoxy, propanoyloxy, butanoyloxy, pivaloyloxy, pentanoyloxy, phenylacetoxy, acetoacetoxy, benzoyloxy, and naphthoyloxy. Examples of the aryloxy group include phenyloxy and naphthyloxy. Examples of the alkenyloxy group include a vinyloxy group, an aryloxy group, a 1-propenyloxy group, an isopropenyloxy group, a 2-butenyloxy group, a 3-butenyloxy group, a 2-pentenyloxy group, a 3-methyl-3-butenyloxy group, and a 2-hexenyloxy group.

Hydrolysis of the hydrolyzable group represented by R⁶ converts the hydrolyzable silyl group represented by Formula (4) to a silanol group. In particular, a methoxy group and an ethoxy group are preferred because they have good hydrolyzability. It is specifically preferred that the hydrolyzable silyl group be a hydrolyzable silyl group in which an oxygen atom having bonds in the structural unit represented by Formula (1) and/or Formula (2) is bonded to or substituted with the above-mentioned hydrolyzable group.

In formation of a coating film through a curing reaction of the group having a polymerizable double bond, since a hydrolysis and condensation reaction proceeds between the hydroxyl group in the silanol group and the hydrolyzable group in the hydrolyzable silyl group in parallel to the curing reaction, the silanol group and the hydrolyzable silyl group contribute to an enhancement in the crosslink density of the polysiloxane structure of the formed coating film, which enables formation of a coating film exhibiting, for example, excellent solvent resistance. Furthermore, the silanol group and the hydrolyzable silyl group serve to link the polysiloxane segment (a1) containing the above-mentioned silanol group or hydrolyzable silyl group to the vinyl polymer segment (a2), which will be described later, through a bond represented by Formula (3).

The polysiloxane segment (a1) may contain any other group without limitation provided that it has the structural unit represented by Formula (1) and/or Formula (2) and contains a silanol group and/or hydrolyzable silyl group. The polysiloxane segment (a1) may, for example, have the following structure without particular limitation: a structure which has both a structural unit in which R¹ in Formula (1) represents the above-mentioned group having a polymerizable double bond and a structural unit in which R¹ in Formula (1) represents an alkyl group such as methyl; a structure which has each of a structural unit in which R¹ in Formula (1) represents the above-mentioned group having a polymerizable double bond, a structural unit in which R¹ in Formula (1) represents an alkyl group such as a methyl group, and a structural unit in which R² and R³ in Formula (2) represent an alkyl group such as a methyl group; or a structure which has both a structural unit in which R¹ in Formula (1) represents the above-mentioned group having a polymerizable double bond and a structural unit in which R² and R³ in Formula (2) represent an alkyl group such as a methyl group.

Specific examples of the polysiloxane segment (a1) include materials having the following structures:

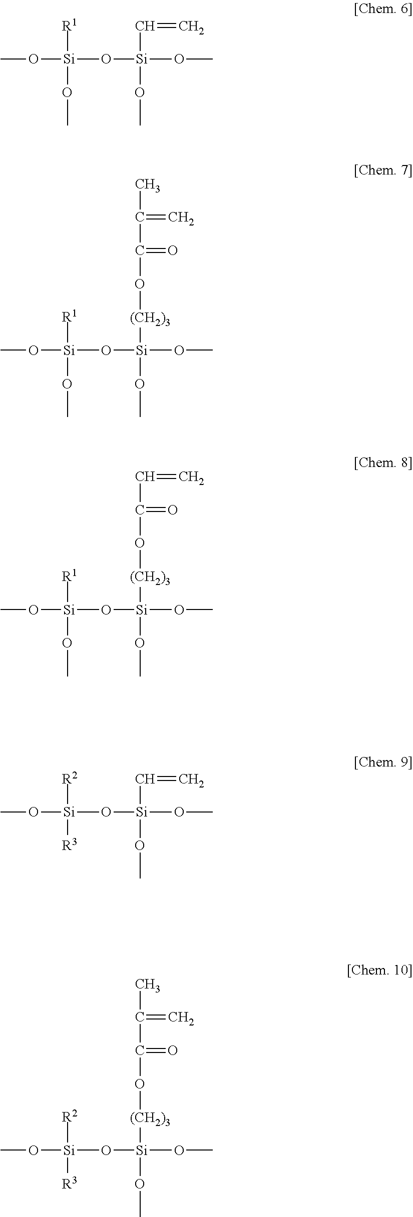

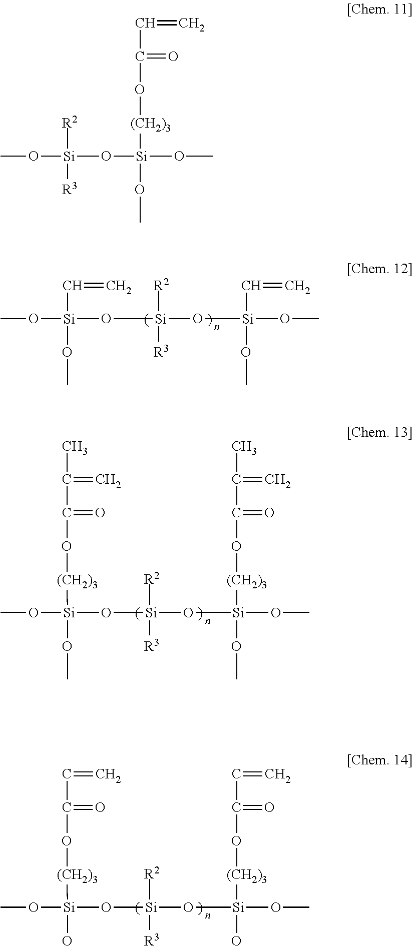

In the present invention, the polysiloxane segment (a1) content is preferably in the range of 10 to 90 weight % relative to the total solid content in the composite resin (A) because it enables both high etching resistance and adhesion to a substrates such as glass. In particular, the polysiloxane segment (a1) content is more preferably 10 to 60 weight %.

(Vinyl Polymer Segment (a2))

The vinyl polymer segment (a2) in the present invention is a vinyl polymer segment such as an acrylic polymer, a fluoroolefin polymer, a vinyl ester polymer, an aromatic vinyl polymer, or a polyolefin polymer.

The acrylic polymer segment can be obtained through polymerization or copolymerization of common (meth)acrylic monomers. Any (meth)acrylic monomer can be used and may be copolymerized with a vinyl monomer. Examples thereof include alkyl(meth)acrylates containing an alkyl group having 1 to 22 carbon atoms, such as methyl(meth)acrylate, ethyl(meth)acrylate, n-propyl(meth)acrylate, n-butyl(meth)acrylate, isobutyl(meth)acrylate, tert-butyl(meth)acrylate, 2-ethylhexyl(meth)acrylate, and lauryl(meth)acrylate; aralkyl(meth)acrylates such as benzyl(meth)acrylate and 2-phenylethyl(meth)acrylate; cycloalkyl(meth)acrylates such as cyclohexyl(meth)acrylate and isobornyl(meth)acrylate; ω-alkoxyalkyl(meth)acrylates such as 2-methoxyethyl(meth)acrylate and 4-methoxybutyl(meth)acrylate; aromatic vinyl monomers such as styrene, p-tert-butylstyrene, α-methylstyrene, and vinyltoluene; vinyl esters of carboxylic acids, such as vinyl acetate, vinyl propionate, vinyl pivalate, and vinyl benzoate; alkyl esters of crotonic acid, such as methyl crotonate and ethyl crotonate; dialkyl esters of unsaturated dibasic acids, such as dimethyl malate, di-n-butyl malate, dimethyl fumarate, and dimethyl itaconate; α-olefins such as ethylene and propylene; fluoroolefins such as vinylidene fluoride, tetrafluoroethylene, hexafluoropropylene, and chlorotrifluoroethylene; alkyl vinyl ethers such as ethyl vinyl ether and n-butyl vinyl ether; cycloalkyl vinyl ethers such as cyclopentyl vinyl ether and cyclohexyl vinyl ether; and tertiary amide group-containing monomers such as N,N-dimethyl(meth)acrylamide, N-(meth)acryloyl morpholine, N-(meth)acryloylpyrrolidine, and N-vinylpyrrolidone.

In order to enhance the dry etching resistance of a resist film that is the nanoimprint-lithographic molded product of the present invention, a (meth)acrylic repeating unit having an aromatic ring or cyclic hydrocarbon group may be introduced into the vinyl polymer segment (a2) in the present invention. Preferred examples of the (meth)acrylic repeating unit having an aromatic ring or cyclic hydrocarbon group include (meth)acrylates having an aromatic ring, such as phenyl(meth)acrylate and benzyl(meth)acrylate; and (meth)acrylate having a cyclic hydrocarbon group, such as cyclohexyl(meth)acrylate, cyclopentanyl(meth)acrylate, adamantyl(meth)acrylate, tricyclodecanyl(meth)acrylate, tetracyclododecanyl(meth)acrylate, dicyclopentanyl(meth)acrylate, ethylene glycol di(meth)acrylate, and isobornyl acrylate. Examples of monomers to be used include ethoxylated bispenol A di(meth)acrylate, propoxylated bispenol A di(meth)acrylate, propoxylated ethoxylated bispenol A di(meth)acrylate, 1,4-cyclohexanedimethanol diacrylate, cyclodecanedimethanol di(meth)acrylate, tricyclo[5.2.1.02,6]decanedimethanol(meth)acrylate, dicyclopentenyl di(meth)acrylate, 1,4-benzenedimethanol di(meth)acrylate, hydrogenated bispenol'A di(meth)acrylate, and 1,3-adamantanediol di(meth)acrylate. These monomers may be used alone or in combination.

(Fluorine-Containing Monomer)

In the composite resin (A), a fluorine-containing monomer may be used for copolymerization. Fluorine contributes to an enhancement in mold release properties in a nanoimprint process and is therefore preferably contained. In the case where a nanoimprint-lithographic molded product serves as a resin mold, good mold release properties are further needed; hence, a fluorine-containing monomer is particularly preferably used for copolymerization.

In the case where the vinyl polymer segment (a2) is copolymerized with a fluorine-containing monomer, a (meth)acrylic monomer containing a fluorinated alkyl group is preferably used.

((Meth)Acrylic Monomer Containing Fluorinated Alkyl Group)

Examples of the (meth)acrylic monomer containing a fluorinated alkyl group (such as a functional group having one carbon atom or two or more carbon atoms linked to each other and having one to three fluorine atoms bonded thereto, a fluorinated alkyl group having a carbon atom which forms an unsaturated bond, or a fluorinated alkyl group having a carbon atom connected by ether linkage through an oxygen atom) include monomers represented by Formula (5).

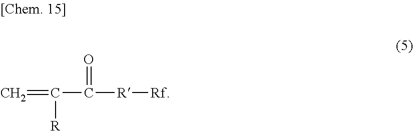

(In Formula (5), R represents a hydrogen atom, a fluorine atom, a methyl group, a cyano group, a phenyl group, a benzyl group, or —CnH2n-Rf′ (n is an integer from 1 to 8, Rf′ represents any one of groups represented by Formulae (Rf-1) to (Rf-7)), R′ represents any one of groups represented by Formulae (R′-1) to (R′-10), and Rf represents any one of groups represented by Formulae (Rf-1) to (Rf-7).)

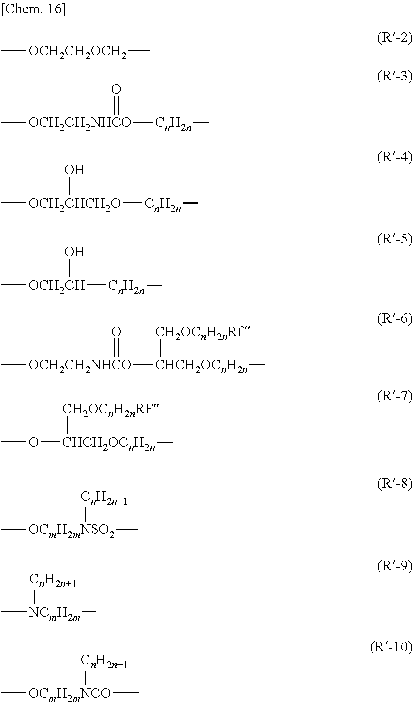

(In Formulae (R′-1), (R′-3), (R′-5), (R′-6), and (R′-7), n is an integer from 1 to 8; in Formulae (R′-8), (R′-9), and (R′-10), m is an integer from 1 to 8, and n is an integer from 0 to 8; in Formulae (R′-6) and (R′-7), Rf″ represents any one of groups represented by Formulae (Rf-1) to (Rf-7).)

[Chem. 17]

—CₙF₂ₙ₊₁ (Rf-1)

—CₙF₂ₙH (Rf-2)

—CₙF₂ₙ₋₁ (Rf-3)

—CₙF₂ₙ₋₃ (Rf-4)

—CₘF₂ₘOCₙF₂ₙCF₃ (Rf-5)

—CₘF₂ₘOCₙF₂ₙOCₚF₂ₚCF₃ (Rf-6)

—CF₂OC₂F₄OC₂F₄OCF₃ (Rf-7)

(In Formulae (Rf-1) and (Rf-2), n is an integer from 1 to 6. In Formula (Rf-3), n is an integer from 2 to 6. In Formula (Rf-4), n is an integer from 4 to 6. In Formula (Rf-5), m is an integer from 1 to 5, n is an integer from 0 to 4, and the total of m and n is from 1 to 5. In Formula (Rf-6), m is an integer from 0 to 4, n is an integer from 1 to 4, p is an integer from 0 to 4, and the total of m, n, and p is from 1 to 5.)

Among the monomers represented by Formula (1), monomers in which a fluorinated alkyl group has 4 to 6 carbon atoms are preferred in terms of high liquid repellency. Specific examples of preferred monomer (f1) include the following monomers (f1-1) to (f1-15).

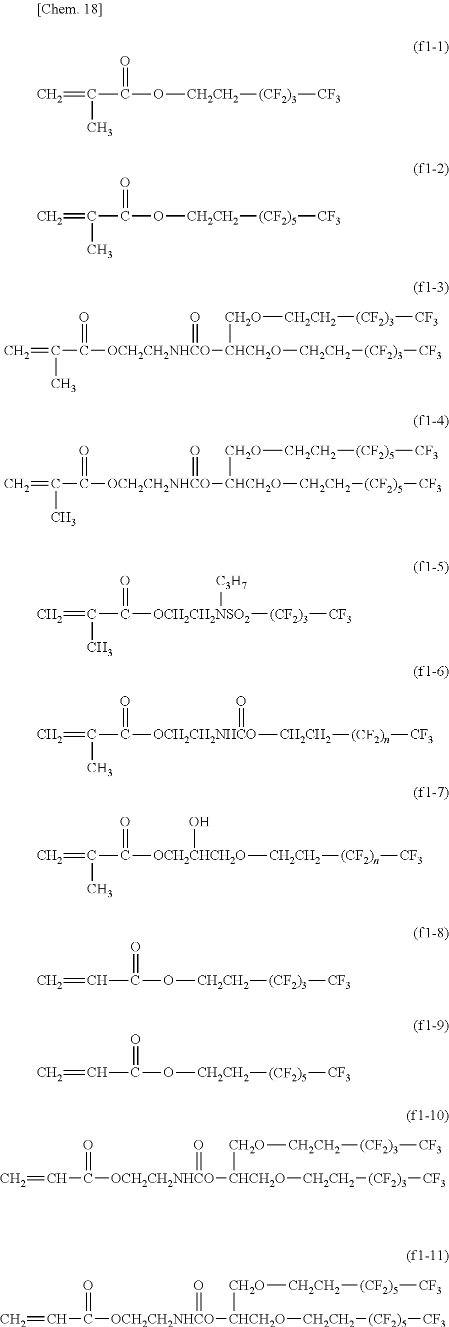

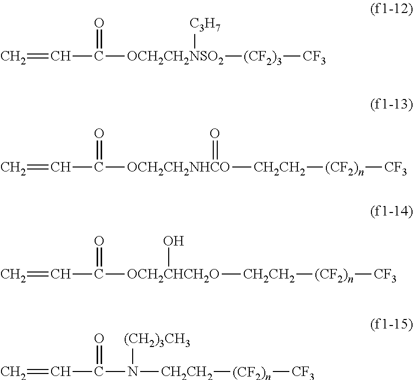

(In Formulae (f1-6), (f1-7), (f1-13), (f1-14), and (f1-13), n represents 3 or 5).

Furthermore, a compound which has a structure site having a poly(perfluoroalkylene ether) chain and radical polymerizable groups at the terminals thereof may be used.

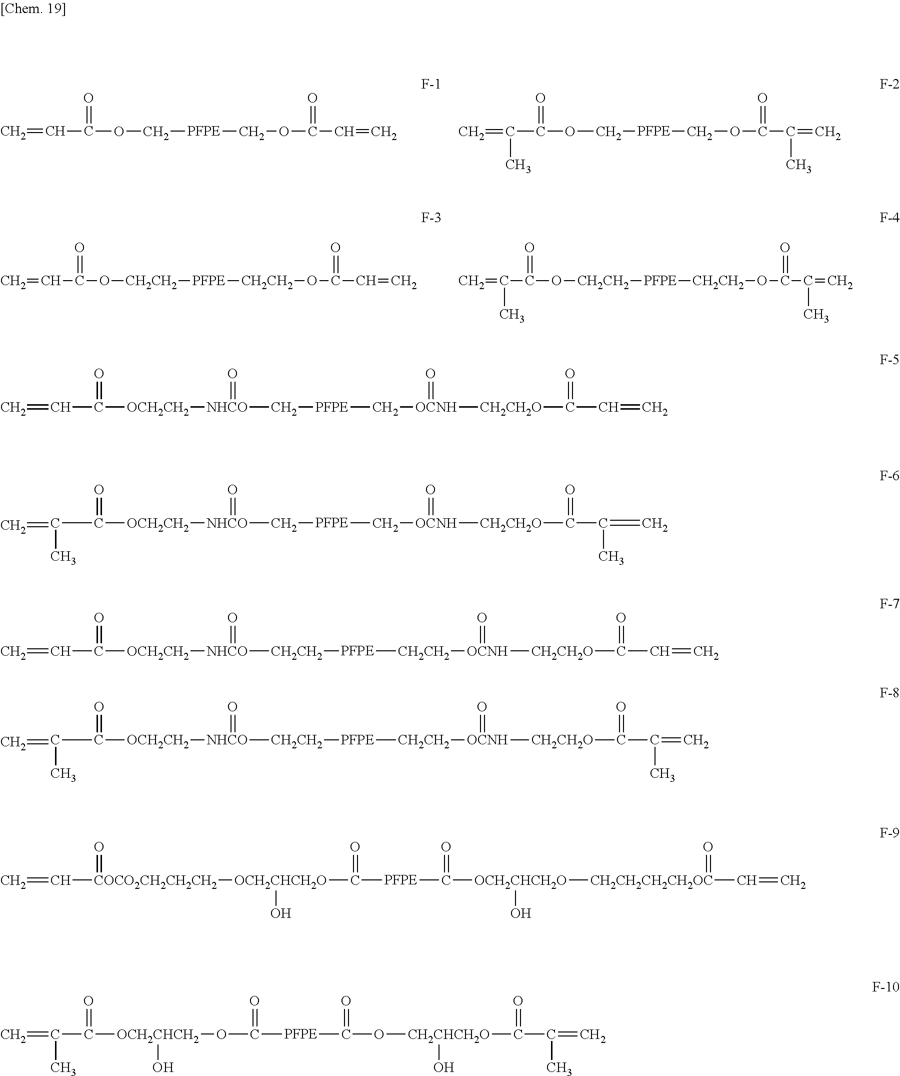

Compounds, for instance, represented by Structural Formulae F-1 to F-10 may be used. In each Structural Formula, “—PFPE-” represents the poly(perfluoroalkylene ether) chain.

(Vinyl Polymer Segment (a2) Containing Acid Radical)

In the case where the nanoimprint-lithographic molded product of the present invention is a resist film or a resin mold, a residual film on the resist film or resin mold is washed with alkali in some cases. In such cases, the nanoimprint-lithographic molded product is preferably soluble in alkali.

In order to produce the nanoimprint-lithographic molded product having an alkali solubility which enables alkali washing, the vinyl polymer segment (a2) in the present invention may be a vinyl polymer segment such as an acrylic polymer, fluoroolefin polymer, vinylester polymer, aromatic vinyl polymer, or polyolefin polymer containing an acid radical. In particular, an acrylic polymer segment produced through copolymerization of a (meth)acrylic monomer containing an acid radical is preferred in terms of the excellent transparency of a coating film to be produced.

Examples of the (meth)acrylic monomer containing an acid radical include a variety of unsaturated carboxylic acids such as a (meth)acrylic acid, 2-carboxyethyl(meth)acrylate, crotonic acid, itaconic acid, maleic acid, and fumaric acid; a variety of monoesters (half-esters) of saturated dicarboxylic acids, such as monomethyl itaconate, mono-n-butyl itaconate, monomethyl maleate, mono-n-butyl maleate, monomethyl fumarate, and mono-n-butyl fumarate, with saturated monohydric alcohols; monovinyl esters of various saturated dicarboxylic acids, such as monovinyl adipate and monovinyl succinate; and anhydrides of various saturated polycarboxylic acids, such as succinic anhydride, glutaric anhydride, phthalic anhydride, and trimellitic anhydride. Among these, a (meth)acrylic acid enables easy reaction and is therefore preferred.

The acid radical content is preferably in the range of 30 to 400 KOHmg/g in terms of the acid value of the composite resin (A). At an acid radial content of not less than 30 KOHmg/g, excellent alkali solubility is exhibited; at an acid radical content of not more than 400 KOHmg/g, gelation is suppressed in synthesis. Hence, such acid radical content is preferred. In particular, an acid radical content of 40 to 300 KOHmg/g enables both good alkali solubility and the good release properties of the resin mold and is therefore preferred.

(Polymerization of Vinyl Polymer Segment (a2))

The above-mentioned monomers can be copolymerized by any polymerization method and with use of any solvent and polymerization initiator, and the vinyl polymer segment (a2) can be formed by well-known methods. The vinyl polymer segment (a2) can be, for example, obtained by a variety of polymerization methods, such as a bulk radical polymerization method, a solution radical polymerization method, and a non-aqueous dispersion radical polymerization method, with use of polymerization initiators such as 2,2′-azobis(isobutyronitrile), 2,2′-azobis(2,4-dimethylvaleronitrile), 2,2′-azobis(2-methylbutyronitrile), tert-butyl peroxypivalate, tert-butyl peroxybenzoate, tert-butyl peroxy-2-ethylhexanoate, di-tert-butyl peroxide, cumene hydroperoxide, and diisopropyl peroxycarbonate.

The number-average molecular weight of the vinyl polymer segment (a2) is preferably in the range of 500 to 200,000 in terms of the number average molecular weight (hereinafter referred to as Mn) because it can prevent thickening or gelation of the composite resin (A) in the production process thereof and enables development of excellent durability. The Mn is more preferably in the range of 700 to 100,000, and further preferably 1,000 to 50,000.

In order to form the composite resin (A) in which the polysiloxane segment (a1) and the vinyl polymer segment (a2) are linked to each other through the bond represented by Formula (3), the vinyl polymer segment (a2) has a silanol group and/or a hydrolyzable silyl group which is directly bonded to a carbon bond in the vinyl polymer segment (a2). Since the silanol group and/or the hydrolyzable silyl group form the bond represented by Formula (3) in the production of the composite resin (A) which will be described later, the vinyl polymer segment (a2) in the composite resin (A) that is the end product contains substantially no silanol group and/or hydrolyzable silyl group. However, even if the silanol group and/or hydrolyzable silyl group remain in the vinyl polymer segment (a2), it does not cause any problem. In formation of a coating film through a curing reaction of the group having a polymerizable double bond, since a hydrolysis and condensation reaction proceeds between the hydroxyl group in the silanol group and the hydrolyzable group in the hydrolyzable silyl group in parallel to the curing reaction, the crosslink density of the polysiloxane structure of the formed coating film is enhanced, which enables formation of a resist film exhibiting, for example, excellent solvent resistance.

In particular, the vinyl polymer segment (a2) having a silanol group and/or hydrolyzable silyl group directly bonded to a carbon bond is formed by copolymerizing the above-mentioned common monomer with a vinyl monomer containing a silanol group and/or hydrolyzable silyl group directly bonded to a carbon bond.

Examples of the vinyl monomer containing a silanol group and/or hydrolyzable silyl group directly bonded to a carbon bond include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. Among these, vinyltrimethoxysilane and 3-(meth)acryloyloxypropyltrimethoxysilane are preferred because they enable easy progress of a hydrolysis reaction and easy removal of by-products after the reaction.

In the case where a polyisocyanate (B) which will be described later is contained, the vinyl polymer segment (a2) preferably contains an alcoholic hydroxyl group. The vinyl polymer segment (a2) containing an alcoholic hydroxyl group can be formed by copolymerization of a (meth)acrylic monomer having an alcoholic hydroxyl group. Specific examples of the (meth)acrylic monomer having an alcoholic hydroxyl group include 2-hydroxyethyl(meth)acrylate, 2-hydroxypropyl(meth)acrylate, 3-hydroxypropyl(meth)acrylate, 2-hydroxybutyl(meth)acrylate, 3-hydroxybutyl(meth)acrylate, 4-hydroxybutyl(meth)acrylate, 3-chloro-2-hydroxypropyl(meth)acrylate, di-2-hydroxyethyl fumarate, mono-2-hydroxyethyl monobutyl fumarate, polyethylene glycol mono(meth)acrylate, polypropylene glycol mono(meth)acrylate, a variety of hydroxyalkyl esters of α,β-ethylene-based unsaturated carboxylic acids, such as “Placcel FM” and “Placcel FA” (caprolactone-modified monomers manufactured by Daicel Chemical Industries, Ltd.), and adducts of ε-caprolactone therewith.

Of these, 2-hydroxyethyl(meth)acrylate is preferably employed because it enables easy reaction.

It is preferred that the amount of the alcoholic hydroxyl group be appropriately determined by calculation from the amount of the polyisocyanate (B) which will be described later.

In addition, in the present invention, an active-energy-ray-curable monomer having an alcoholic hydroxyl group may be preferably used in combination as described below. Accordingly, the amount of the alcoholic hydroxyl group in the vinyl polymer segment (a2) having an alcoholic hydroxyl group can be determined in consideration of even the amount of the active-energy-ray-curable monomer having an alcoholic hydroxyl group, which is to be used in combination. It is preferred that the amount of the alcoholic hydroxyl group be substantially in the range of 30 to 300 in terms of the hydroxyl value of the vinyl polymer segment (a2).

(Production Method of Composite Resin (A))

The composite resin (A) used in the present invention is specifically produced by (Method 1) to (Method 3).

(Method 1) The above-mentioned common (meth)acrylic monomer or another material and the above-mentioned vinyl monomer containing a silanol group and/or hydrolyzable silyl group directly bonded to a carbon bond are copolymerized to produce the vinyl polymer segment (a2) containing a silanol group and/or hydrolyzable silyl group directly bonded to a carbon bond. This vinyl polymer segment (a2) is mixed with a silane compound having a silanol group and/or hydrolyzable silyl group as well as having a polymerizable double bond and optionally with a common silane compound to induce a hydrolysis and condensation reaction.

In this method, the silanol group or hydrolyzable silyl group of the silane compound having a silanol group and/or hydrolyzable silyl group as well as having a polymerizable double bond and the silanol group and/or hydrolyzable silyl group of the vinyl polymer segment (a2) having a silanol group and/or hydrolyzable silyl group directly bonded to a carbon bond are subjected to the hydrolysis and condensation reaction, thereby forming the polysiloxane segment (a1) with the result that a composite resin (A) in which the polysiloxane segment (a1) and the vinyl polymer segment (a2) are combined through the bond represented by Formula (3) is yielded.

(Method 2) The vinyl polymer segment (a2) containing a silanol group and/or hydrolyzable silyl group directly bonded to a carbon bond is formed as in Method 1. The polysiloxane segment (a1) is formed through a hydrolysis and condensation reaction of a silane compound having a silanol group and/or a hydrolyzable silyl group as well as having a polymerizable double bond; a common silane compound may be optionally used. Then, the silanol group and/or hydrolyzable silyl group of the vinyl polymer segment (a2) and the silanol group and/or hydrolyzable silyl group of the polysiloxane segment (a1) are subjected to a hydrolysis and condensation reaction.

(Method 3) The vinyl polymer segment (a2) containing a silanol group and/or hydrolyzable silyl group directly bonded to a carbon bond is produced as in Method 1. The polysiloxane segment (a1) is produced as in Method 2. Then, a silane compound which is a silane compound having a polymerizable double bond and optionally a common silane compound are mixed therewith to induce a hydrolysis and condensation reaction.

Specific examples of the silane compound having a silanol group and/or hydrolyzable silyl group as well as having a polymerizable double bond, which are used in (Method 1) to (Method 3), include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. Among these, vinyltrimethoxysilane and 3-(meth)acryloyloxypropyltrimethoxysilane are preferred because they enable easy progress of a hydrolysis reaction and easy removal of by-products after the reaction.

Examples of the common silane compound used in (Method 1) to (Method 3) include a variety of organotrialkoxysilanes such as methyltrimethoxysilane, methyltriethoxysilane, methyltri-n-butoxysilane, ethyltrimethoxysilane, n-propyltrimethoxysilane, iso-butyltrimethoxysilane, cyclohexyltrimethoxysilane, phenyltrimethoxysilane, and phenyltriethoxysilane; a variety of diorganodialkoxysilanes such as dimethyldimethoxysilane, dimethyldiethoxysilane, dimethyldi-n-butoxysilane, diethyldimethoxysilane, diphenyldimethoxysilane, methylcyclohexyldimethoxysilane, and methylphenyldimethoxysilane; and chlorosilanes such as methyltrichlorosilane, ethyltrichlorosilane, phenyltrichlorosilane, vinyltrichlorosilane, dimethyldichlorosilane, diethyldichlorosilane, and diphenyldichlorosilane. Among these, organotrialkoxysilane and diorganodialkoxysilane are preferred because they enable easy progress of a hydrolysis reaction and easy removal of by-products after the reaction.

Furthermore, epoxy group-containing silane compounds can be used. Examples of the epoxy group-containing silane compounds include γ-glycidoxypropyltrimethoxysilane, γ-glycidoxypropyltriethoxysilane, γ-glycidoxypropyltrimethoxyethoxysilane, γ-glycidoxypropyltriacetoxysilane, β-(3,4-epoxycyclohexyl)ethyltrimethoxysilane, β-(3,4-epoxycyclohexyl)ethyltriethoxysilane, β-(3,4-epoxycyclohexyl)ethyltrimethoxyethoxysilane, β-(3,4-epoxycyclohexyl)ethyltriacetoxysilane, γ-glycidoxypropyldimethoxymethylsilane, γ-glycidoxypropyldiethoxymethylsilane, γ-glycidoxypropyldimethoxyethoxymethylsilane, γ-glycidoxypropyldiacetoxymethylsilane, β-(3,4-epoxycyclohexyl)ethyldimethoxymethylsilane, β-(3,4-epoxycyclohexyl)ethyldiethoxymethylsilane, β-(3,4-epoxycyclohexyl)ethyldimethoxyethoxymethylsilane, β-(3,4-epoxycyclohexyl)ethyldiacetoxymethylsilane, γ-glycidoxypropyldimethoxyethylsilane, γ-glycidoxypropyldiethoxyethylsilane, γ-glycidoxypropyldimethoxyethoxyethylsilane, γ-glycidoxypropyldiacetoxyethylsilane, β-(3,4-epoxycyclohexyl)ethyldimethoxyethylsilane, β-(3,4-epoxycyclohexyl)ethyldiethoxyethylsilane, β-(3,4-epoxycyclohexyl)ethyldimethoxyethoxyethylsilane, β-(3,4-epoxycyclohexyl)ethyldiacetoxyethylsilane, γ-glycidoxypropyldimethoxyisopropylsilane, γ-glycidoxypropyldiethoxyisopropylsilane, γ-glycidoxypropyldimethoxyethoxyisopropylsilane, γ-glycidoxypropyldiacetoxyisopropylsilane, β-(3,4-epoxycyclohexyl)ethyldiethoxyisopropylsilane, β-(3,4-epoxycyclohexyl)ethyldiethoxyisopropylsilane, β-(3,4-epoxycyclohexyl)ethyldimethoxyethoxyisopropylsilane, β-(3,4-epoxycyclohexyl)ethyldiacetoxyisopropylsilane, γ-glycidoxypropylmethoxydimethylsilane, γ-glycidoxypropylethoxydimethylsilane, γ-glycidoxypropylmethoxyethoxydimethylsilane, γ-glycidoxypropylacetoxydimethylsilane, β-(3,4-epoxycyclohexyl)ethylmethoxydimethylsilane, β-(3,4-epoxycyclohexyl)ethylethoxydimethylsilane, β-(3,4-epoxycyclohexyl)ethylmethoxyethoxydimethylsilane, β-(3,4-epoxycyclohexyl)ethylacetoxydimethylsilane, γ-glycidoxypropylmethoxydiethylsilane, γ-glycidoxypropylethoxydiethylsilane, γ-glycidoxypropylmethoxyethoxydiethylsilane, γ-glycidoxypropylacetoxydiethylsilane, β-(3,4-epoxycyclohexyl)ethylmethoxydiethylsilane, β-(3,4-epoxycyclohexyl)ethylethoxydiethylsilane, β-(3,4-epoxycyclohexyl)ethylmethoxyethoxydiethylsilane, β-(3,4-epoxycyclohexyl)ethylacetoxydiethylsilane, γ-glycidoxypropylmethoxydiisopropylsilane, γ-glycidoxypropylethoxydiisopropylsilane, γ-glycidoxypropylmethoxyethoxydiisopropylsilane, γ-glycidoxypropylacetoxydiisopropylsilane, β-(3,4-epoxycyclohexyl)ethylmethoxydiisopropylsilane, β-(3,4-epoxycyclohexyl)ethylethoxydiisopropylsilane, β-(3,4-epoxycyclohexyl)ethylmethoxyethoxydiisopropylsilane, β-(3,4-epoxycyclohexyl)ethylacetoxydiisopropylsilane, γ-glycidoxypropylmethoxyethoxymethylsilane, γ-glycidoxypropylacetoxymethoxymethylsilane, γ-glycidoxypropylacetoxyethoxymethylsilane, β-(3,4-epoxycyclohexyl)ethylmethoxyethoxymethylsilane, β-(3,4-epoxycyclohexyl)ethylmethoxyacetoxymethylsilane, β-(3,4-epoxycyclohexyl)ethylethoxyacetoxymethylsilane, γ-glycidoxypropylmethoxyethoxyethylsilane, γ-glycidoxypropylacetoxymethoxyethylsilane, γ-glycidoxypropylacetoxyethoxyethylsilane, β-(3,4-epoxycyclohexyl)ethylmethoxyethoxyethylsilane, β-(3,4-epoxycyclohexyl)ethylmethoxyacetoxyethylsilane, β-(3,4-epoxycyclohexyl)ethylethoxyacetoxyethylsilane, γ-glycidoxypropylmethoxyethoxyisopropylsilane, γ-glycidoxypropylacetoxymethoxyisopropylsilane, γ-glycidoxypropylacetoxyethoxyisopropylsilane, β-(3,4-epoxycyclohexyl)ethylmethoxyethoxyisopropylsilane, β-(3,4-epoxycyclohexyl)ethylmethoxyacetoxyisopropylsilane, β-(3,4-epoxycyclohexyl)ethylethoxyacetoxyisopropylsilane, glycidoxymethyltrimethoxysilane, glycidoxymethyltriethoxysilane, α-glycidoxyethyltrimethoxysilane, α-glycidoxymethyltrimethoxysilane, β-glycidoxyethyltrimethoxysilane, β-glycidoxymethyltrimethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltrimethoxysilane, β-glycidoxybutyltriethoxysilane, γ-glycidoxybutyltrimethoxysilane, γ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylmethyldiethoxysilane, α-glycldoxypropylmethyldimethoxysilane, α-glycidoxypropylmethyldiethoxysilane, β-glycidoxypropylmethyldimethoxysilane, β-glycidoxypropylmethyldiethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldimethoxyethoxysilane, γ-glycidoxypropylmethyldiphenoxysilane, γ-glycidoxypropylethyldimethoxysilane, γ-glycidoxypropylethyldiethoxysilane, γ-glycidoxypropylethyldipropoxysilane, γ-glycidoxypropylvinyldimethoxysilane, and γ-glycidoxypropylvinyldiethoxysilane.

A silane coupling agent containing a fluorinated alkyl group can be used, such as trifluoropropyltrimethoxysilane. An example of a commercially available product thereof is KBM-7013 manufactured by Shin-Etsu Chemical Co., Ltd. The composite resin (A) containing a fluorine atom enable's production of a resin mold having excellent mold release properties and is therefore especially preferred.

In addition, a tetrafunctional alkoxysilane compound, such as tetramethoxysilane, tetraethoxysilane, or tetra-n-propoxysilane, or a partial hydrolytic condensate of such a tetrafunctional alkoxysilane compound can be additionally used provided that the effects of the present invention are not be impaired. It is preferred that the tetrafunctional alkoxysilane compound or a partial hydrolytic condensate thereof be additionally used such that silicon atom content in the tetrafunctional alkoxysilane compound does not exceed 20 mol % relative to the total amount of the silicon atoms contained in the polysiloxane segment (a1).

Moreover, an alkoxide compound of metal atoms other than silicon atoms, such as boron, titanium, zirconium, or aluminum atoms, can be used in combination with the silane compound provided that the effects of the present invention are not impaired. For example, such an alkoxide compound is preferably used such that the metal atom content in the alkoxide compound does not exceed 25 mol % relative to the total amount of the silicon atoms contained in the polysiloxane segment (a1).

The hydrolysis and condensation reaction in (Method 1) to (Method 3) refers to the following condensation reaction: some of the above-mentioned hydrolyzable groups are hydrolyzed due to the effect of, for example, water to form hydroxyl groups, and then the reaction proceeds between the hydroxyl groups or between the hydroxyl groups and hydrolyzable groups. The hydrolysis and condensation reaction can be promoted by well-known methods, and a method in which water and a catalyst are supplied in the production process to promote the reaction is easy and simple; hence such a method is preferably employed.

Examples of the catalyst to be used include inorganic acids such as hydrochloric acid, sulfuric acid, and phosphoric acid; organic acids such as p-toluenesulfonic acid, monoisopropyl phosphate, and acetic acid; inorganic bases such as sodium hydroxide and potassium hydroxide; titanate esters such as tetraisopropyl titanate and tetrabutyl titanate; compounds containing a variety of basic nitrogen atoms, such as 1,8-diazabicyclo[5.4.0]undecene-7 (DBU), 1,5-diazabicyclo[4.3.0]nonene-5 (DBN), 1,4-diazabicyclo[2.2.2]octane (DABCO), tri-n-butylamine, dimethylbenzylamine, monoethanolamine, imidazole, and 1-methylimidazole; a variety of quaternary ammonium salts such as a tetramethylammonium salt, a tetrabutylammonium salt, and a dilauryldimethylammonium salt, which contain counter anions such as chloride, bromide, carboxylate, and hydroxide; and tin carboxylate salts such as dibutyltin diacetate, dibutyltin dioctoate, dibutyltin dilaurate, dibutyltin diacetylacetonato, tin octylate, and tin stearate. These catalysts may be used alone or in combination.

The amount of the catalyst is not specifically limited; in general, the amount of the catalyst is preferably in the range of 0.0001 to 10 weight %, more preferably 0.0005 to 3 weight %, and especially preferably 0.001 to 1 weight % relative to the total amount of the above-mentioned individual compounds having silanol groups or hydrolyzable silyl groups.

The amount of water to be supplied is preferably 0.05 moles or more, more preferably 0.1 mole or more, and especially preferably 0.5 moles or more relative to 1 mole of the silanol groups or hydrolyzable silyl groups of the above-mentioned individual compounds having the silanol groups or hydrolyzable silyl groups. These catalyst and water may be supplied either at the same time or one by one. Alternatively, a catalyst and water may be preliminarily mixed and then supplied.

The reaction temperature at which the hydrolysis and condensation reaction is carried out in (Method 1) to (Method 3) is appropriately in the range of 0° C. to 150° C., and preferably 20° C. to 100° C. The reaction can be carried out under any pressure condition, such as under normal pressure, increased pressure, or reduced pressure. Alcohol and water which are by-products that may be generated in the hydrolysis and condensation reaction may be optionally removed by distillation or another technique.

The percentages of the individual compounds fed in (Method 1) to (Method 3) are appropriately selected on the basis of the intended structure of, the composite resin (A) used in the present invention. In particular, the composite resin (A) is produced such that the polysiloxane segment (a1) content is from 30 to 95 weight %, and more preferably 30 to 75 weight % because it enables production of a coating film having an excellent durability.

In (Method 1) to (Method 3), the polysiloxane segment and the vinyl polymer segment are specifically combined into a block structure by, for instance, the following technique: a vinyl polymer segment having a structure in which the above-mentioned silanol group and/or hydrolyzable silyl group is present only at one or two terminals of its polymer chain is used as an intermediate, and, for example in (Method 1), this vinyl polymer segment is mixed with a silane compound having a silanol group and/or hydrolyzable silyl group as well as having a polymerizable double bond and optionally with a common silane compound to induce a hydrolysis and condensation reaction.

In (Method 1) to (Method 3), the polysiloxane segment is specifically grafted onto the vinyl polymer segment by, for instance, the following technique: a vinyl polymer segment having a structure in which the above-mentioned silanol group and/or hydrolyzable silyl group is randomly distributed on the main chain of the vinyl polymer segment is used as an intermediate, and, for example in (Method 2), the silanol group and/or hydrolyzable silyl group of the vinyl polymer segment and the silanol group and/or hydrolyzable silyl group of the above-mentioned polysiloxane segment are subjected to a hydrolysis and condensation reaction.

(Polyisocyanate (B))

In the case where the vinyl polymer segment (a2) of the composite resin (A) contains an alcoholic hydroxyl group, polyisocyanate (B) is preferably used in combination.

Any known polyisocyanates can be used as the polyisocyanate (B). Examples thereof include polyisocyanates mainly synthesized from aromatic diisocyanates such as tolylene diisocyanate and diphenylmethane-4,4′-diisocyanate and from aralkyl diisocyanates such as meta-xylylene diisocyanate and α,α,α′,α′-tetramethyl-meta-xylylene diisocyanate; and tetramethylene diisocyanate, 1,5-pentamethylene diisocyanate, 1,6-hexamethylene diisocyanate (hereinafter referred to as “HDI”), 2,2,4-(or 2,4,4)-trimethyl-1,6-hexamethylene diisocyanate, lysine isocyanate, isophorone diisocyanate, hydrogenated xylene diisocyanate, hydrogenated diphenylmethane diisocyanate, 1,4-diisocyanate cyclohexane, 1,3-bis(diisocyanate methyl)cyclohexane, 4,4′-dicyclohexylmethane diisocyanate, allophanate-modified polyisocyanates, biuret-modified polyisocyanates, adducts of polyisocyanates, and isocyanurate-modified polyisocyanates.

Furthermore, blocked polyisocyanate compounds synthesized through blocking by a variety of blocking agents can also be used as the above-mentioned polyisocyanate. Examples of such blocking agents include alcohols such as methanol, ethanol, and lactate; phenolic hydroxyl group-containing compounds, such as phenol and salicylate; amides such as ε-caprolactam and 2-pyrrolidone; oximes such as acetone oxime and methylethylketoxime; and active methylene compounds such as methyl acetoacetate, ethyl acetoacetate, and acetylacetone.

In the reaction between the polyisocyanate and the hydroxyl groups in the system (the hydroxyl group in the vinyl polymer segment (a2) and the hydroxyl group in the active-energy-ray-curable monomer having an alcoholic hydroxyl group, which will be described later), heating or another treatment is not necessarily carried out. For example, in the case where curing is carried out by irradiation with UV light, a coating film is left to stand at room temperature after being irradiated with UV light with the result that the reaction gradually progresses. Moreover, heating may be optionally carried out for several minutes to several hours (20 minutes to 4 hours) at 80° C. after the irradiation with UV light to promote the reaction between the alcoholic hydroxyl group and the isocyanate. In this case, a known urethanation catalyst may be optionally used. The urethanation catalyst is properly selected on the basis of the intended reaction temperature.

(Nanoimprint Curable Composition)

The nanoimprint curable composition of the present invention contains a photopolymerization initiator. Known photopolymerization initiators used for photocurable compositions may be employed; for example, at least one photopolymerization initiator selected from the group consisting of acetophenones, benzyl ketals, and benzophenones can be preferably used. Examples of the acetophenones include diethoxyacetophenone, 2-hydroxy-2-methyl-1-phenylpropane-1-one, 1-(4-isopropylphenyl)-2-hydroxy-2-methylpropane-1-one, and 4-(2-hydroxyethoxy)phenyl-(2-hydroxy-2-propyl)ketone. Examples of the benzyl ketals include 1-hydroxycyclohexyl-phenyl ketone and benzyl dimethyl ketal. Examples of the benzophenones include benzophenone and methyl o-benzoylbenzoate. Examples of the benzoins include benzoin, benzoin methyl ether, and benzoin isopropyl ether. These photopolymerization initiators may be used alone or in combination.

The amount of the photopolymerization initiator is preferably from 1 to 15 weight %, and more preferably from 2 to 10 weight % relative to 100 weight % of the composite resin (A).

In the case where the composite resin (A) contains a cationically photopolymerizable group such as a vinyl ether group or an epoxy group, a cationic photoinitiator can also be used. Examples of the cationic photoinitiator include diazonium salts of Lewis acids, iodonium salts of Lewis acids, and sulfonium salts of Lewis acids. These cationic photoinitiators are onium salts of which the cation portions are an aromatic diazonium, an aromatic iodonium, and an aromatic sulfonium, respectively, and of which the anion portions are composed of, for instance, BF4-, PF6-, SbF6-, and [BY4]- (wherein Y represents a phenyl group substituted with at least two fluorine atoms or trifluoromethyl groups). In terms of stability, cationic polymerization initiators that are phosphorus compounds are preferably employed. Specific examples thereof include a phenyldiazonium salt, of boron tetrafluoride, a diphenyliodonium salt of phosphorus hexafluoride, a diphenyliodonium salt of antimony hexafluoride, a tri-4-methylphenylsulfonium salt of arsenic hexafluoride, a tri-4-methylphenylsulfonium salt of antimony tetrafluoride, a diphenyliodonium salt of tetrakis(pentafluorophenyl)boron, a mixture of an acetylacetone aluminium salt and an orthonitrobenzyl silyl ether, a phenylthiopyridium salt, and a phosphorus hexafluoride allene-iron complex.

In the case where ultraviolet curing is carried out, it is preferred that a polyfunctional (meth)acrylate be properly used. If the polyfunctional (meth)acrylate is allowed to react with the polyisocyanate (B), a polyfunctional (meth)acrylate having an alcoholic hydroxyl group is preferably employed. Examples of such a polyfunctional (meth)acrylate include polyfunctional (meth)acrylates having two or more polymerizable double bonds in a molecule, such as 1,2-ethanediol diacrylate, 1,2-propanediol diacrylate, 1,4-butanediol diacrylate, 1,6-hexanediol diacrylate, dipropylene glycol diacrylate, neopentyl glycol diacrylate, tripropylene glycol diacrylate, trimethylol propane diacrylate, trimethylol propane triacrylate, tris(2-acryloyloxy)isocyanurate, pentaerythritol triacrylate, pentaerythritol tetraacrylate, di(trimethylol propane)tetraacrylate, di(pentaerythritol)pentaacrylate, and di(pentaerythritol)hexaacrylate. In addition, examples of the polyfunctional acrylate further include a urethane acrylate, a polyester acrylate, and an epoxy acrylate. These materials may be used alone or in combination.

Among these, pentaerythritol triacrylate and di(pentaerythritol)pentaacrylate are preferably employed.

Furthermore, a monofunctional (meth)acrylate can be used in combination with the above-mentioned polyfunctional (meth)acrylate. Examples of such a monofunctional (meth)acrylate include hydroxyl group-containing (meth)acrylate esters such as hydroxyethyl(meth)acrylate, hydroxypropyl(meth)acrylate, hydroxybutyl(meth)acrylate, caprolactone-modified hydroxy(meth)acrylate (e.g., “Placcel (trade name)” manufactured by Daicel Chemical Industries, Ltd.), mono(meth)acrylates of polyester diol prepared from phthalic acid and propylene glycol, mono(meth)acrylates of polyester diol prepared from succinic acid and propylene glycol, polyethylene glycol mono(meth)acrylate, polypropylene glycol mono(meth)acrylate, pentaerythritol tri(meth)acrylate, 2-hydroxy-3-(meth)acryloyloxypropyl(meth)acrylate, and (meth)acrylate adducts of a variety of epoxy esters; carboxyl group-containing vinyl monomers such as (meth)acrylic acid, crotonic acid, itaconic acid, maleic acid, and fumaric acid; sulfonic acid group-containing vinyl monomers such as vinylsulfonic acid, styrenesulfonic acid, and sulfoethyl(meth)acrylate; acidic phosphate ester-based vinyl monomers such as 2-(meth)acryloyloxyethyl acid phosphate, 2-(meth)acryloyloxypropyl acid phosphate, 2-(meth)acryloyloxy-3-chloro-propyl acid phosphate, and 2-methacryloyloxyethyl phenyl phosphate; and methylol group-containing vinyl monomers such as N-methylol(meth)acrylamide. These materials may be used alone or in combination.

The amount of the polyfunctional acrylate (C) is preferably from 1 to 85 weight %, more preferably 5 to 80 weight % relative to the total solid content of the nanoimprint curable composition of the present invention. Use of the polyfunctional acrylate in such an amount can contribute to enhancements in pattern formability and pattern-holding properties.

The nanoimprint curable composition of the present invention can be formed into a shape by any technique. In the case where a nanoimprint-lithographic molded product is formed with a master mold after a coating film is formed by, for example, a coating technique, the viscosity is preferably adjusted with an organic solvent. In view of coating properties (e.g., enabling the thickness of a film to be within an intended range after application of the composition and removal of the solvent, enabling such a thickness to be uniform on the entire target surface, and enabling a coating film having a uniform thickness to be formed so as to cover some unevenness of, a target surface), the solid content concentration is preferably in the range of 0.1 weight % to 10 weight %, more preferably 0.4 weight % to 5 weight %, and further preferably 0.7 weight % to 2 weight %. In particular, the viscosity is adjusted such that the coating film has a thickness ranging from 10 nm to 50 μm, and preferably 50 nm to 5 μm.

Known organic solvents can be used provided that the effects of the invention are not impaired. Examples thereof include aliphatic or alicyclic hydrocarbons such as n-hexane, n-heptane, n-octane, cyclohexane, and cyclopentane; aromatic hydrocarbons such as toluene, xylene, and ethylbenzene; alcohols such as methanol, ethanol, n-butanol, ethylene glycol monomethyl ether, and propylene glycol monomethyl ether; esters such as ethyl acetate, butyl acetate, n-butyl acetate, n-amyl acetate, ethylene glycol monomethyl ether acetate, and propylene glycol monomethyl ether acetate; ketones such as acetone, methyl ethyl ketone, methyl isobutyl ketone, methyl n-amyl ketone, and cyclohexanone; polyalkylene glycol dialkyl ethers such as diethylene glycol dimethyl ether and diethylene glycol dibutyl ether; ethers such as 1,2-dimethoxyethane, tetrahydrofuran, and dioxane; and N-methylpyrrolidone, dimethylformamide, dimethylacetamide, and ethylene carbonate. These organic solvents can be used alone or in combination.

(Method for Forming Pattern)

The method for forming a pattern by nanoimprint lithography according to the present invention can be appropriately carried out. The method may be carried out, for instance, in the following manner: the nanoimprint curable composition of the present invention is applied to a substrate to form a film, a master mold is subsequently pressed against the film, and then the film is cured in this state; or the nanoimprint curable composition is put into a forming die, a master mold is subsequently pressed against the curable composition, and then curing is carried out in this state. Furthermore, the method may be carried out as follows: a nano-sized concave-convex structure is formed in a forming die, into which the nanoimprint curable composition is to be put, to allow the forming die itself to serve as a master mold, and the nanoimprint curable composition is put into such a forming die and then cured. In view of the high throughput in a molding process, the method which involves applying the nanoimprint curable composition of the present invention to a substrate to form a film, subsequently pressing a master mold against the film, and then curing the film in this state is especially preferred.

A method for forming a pattern will now be described in detail, which involves a process of forming a film by applying the nanoimprint curable composition of the present invention to a substrate, a process of curing the curable resin composition by irradiation with an active energy ray in a state in which a nanoimprint mold having a concave-convex structure is pressed against the curable composition, and a process of subsequently removing the mold.

In the process of forming a coating film by applying the nanoimprint curable composition of the present invention to a substrate, the nanoimprint curable composition of the present invention which has been adjusted to have a desired viscosity as described above is preferably used to form a film or a coating film by a known technique.

A film may be formed by, for example, an extrusion technique; alternatively, the film may be laminated by being thermally press-bonded to a surface of a target product as follows: the nanoimprint curable composition is applied to a temporal support film and then dried, and the surface of the layer of the nanoimprint curable composition is optionally covered with a film. Examples of the temporal support film to be used include well-known films such as a polyethylene terephthalate film, a polyimide film, a polyamide-imide film, a polypropylene film, and a polystyrene film. In the case where such a temporal support film has properties necessary for formation of coating films, such as solvent resistance or thermal resistance, the nanoimprint curable composition of the present invention can be directly applied onto the temporal support film and then dried to form a coating film. Even in the case where the temporal support film has a low solvent resistance or low thermal resistance, a layer of the nanoimprint curable composition of the present invention is preliminarily formed on a film having mold release properties, such as a polytetrafluoroethylene film or a mold release film, the temporal support film having a low solvent resistance or low thermal resistance is subsequently laminated thereon, and then the film having mold release properties is removed to form a coating film.

A coating film may be formed by applying the nanoimprint curable composition of the present invention onto a surface of a target product and then removing a solvent by volatilization. Examples of an application technique include spraying, spin coating, dipping, roll coating, blade coating, doctor rolling, doctor blading, curtain coating, slit coating, and screen printing. Spin coating is preferably employed because it enables high productivity and easy control of the thickness of a film.

(Substrate)

The substrate used in the present invention to form a laminate is appropriately selected on the basis of intended use of the nanoimprint cured product of the present invention. Examples of the substrate include quartz substrates; sapphire substrates; glass substrates; optical films; substrates formed of ceramic materials; vapor deposited films; magnetic films; reflection films; substrates formed of metal such as Al, Ni, Cu, Cr, Fe, and stainless steel; screen mesh; paper; wood; substrates made of synthetic resins such as silicone; SOG (Spin On Glass); polymer substrates such as a polyester film, a polycarbonate film, and a polyimide film; TFT array substrates; light emitting diode (LED) substrates such as a sapphire substrate and a GaN substrate; glass substrates and transparent plastic substrates; conducive substrates formed of, for example, indium tin oxide (ITO) and metal; insulating substrates; and substrates used for forming semiconductor devices, such as a silicon substrate, a silicon nitride substrate, a polysilicon substrate, a silicon oxide substrate, and an amorphous silicon substrate. These substrates may transmit light or may not transmit light. The substrate may be in any form on the basis of intended use, such as a plate, a sheet, or a product having an entirely or partially curved three-dimensional geometry. Furthermore, the substrate may have any hardness and thickness. The thickness largely depends on the intended depth of a concave-convex structure and preferably ranges from 0.001 to 300 μm.

In a process of pressing a nanoimprint master mold having a concave-convex structure against the film formed as described above, in particular, the layer of the nanoimprint curable composition is allowed to intrude into the fine pattern of the nanoimprint master mold while the master mold is pressed. In this case, in order to further transfer the fine pattern of the master mold to the nanoimprint curable composition, the master mold may be pressed while heating is carried out to decrease the viscosity. Then, the layer of the nanoimprint curable composition is cured by being irradiated with ultraviolet light, and the master mold is subsequently separated to obtain a resist film in which the fine pattern of the master mold has been formed in the surface of the nanoimprint curable composition.

In particular, a nanoimprint master mold is brought into contact with the layer of the nanoimprint curable composition, which has been formed on the surface of the substrate; in this case, the nanoimprint master mold is pressed against the layer of the nanoimprint curable composition such that the layer is pinched. In order to efficiently form a large-scale molded product, the nanoimprint master mold is also preferably brought into contact with the layer of the nanoimprint curable composition by the following techniques: a technique which is suitable for a roll process and in which a planar original plate moves up and down, a bonding technique which involves use of a belt-like original plate, a roll transfer technique which involves use of a roller-like original plate, and a roll transfer technique which involves use of a roller-belt-like original plate. Examples of the material used for the master mold include light-transmitting materials, e.g., quartz glass, ultraviolet-transmitting glass, sapphire, diamond, silicon materials such as polydimethylsiloxane, fluororesin, and other light-transmitting materials composed of resins. If the substrate to be used is formed of a light-transmitting material, the master mold may be formed of a material which does not transmit light. Examples of the material which does not transmit light include metal, silicon, Sic, and mica.

As described above, the master mold to be used can be in any form such as a plate, belt, roller, or roller belt. In order to prevent the original plate from being polluted by, for instance, floating dust, the transfer surface is preferably subjected to well-known mold release treatments.

(Curing Process)

The curing is, for example, carried out by irradiation with light from the master mold side in the case where the master mold is formed of a light-transmitting material or by irradiation with light from the substrate side in the case where the substrate is formed of a light-transmitting material. In the case where both the mold and substrate are formed of light-transmitting materials, light may be emitted from both sides. Any type of light which induces the reaction of the photopolymerization initiator can be emitted; in particular, light having a wavelength of not more than 450 nm (e.g., an active energy ray such as ultraviolet ray, X-ray, or γ-ray) is preferably used because it easily induces the reaction of the photopolymerization initiator and enables curing at lower temperature. In terms of the convenience of operation, light having a wavelength of 200 to 450 nm is especially preferably employed. In particular, light used for the above-mentioned ultraviolet curing can be employed.

In the case where the concave-convex structure of a coating film is not sufficiently transferred to a coating film, heating may be carried out during irradiation with light to a temperature which enables development of sufficient flowability. The temperature in the heating is preferably not more than 300° C., more preferably 0° C. to 200° C., further preferably 0° C. to 150° C., and especially preferably 25° C. to 80° C. Within such a temperature range, the precision of the fine pattern formed in the layer of the curable resin composition is highly maintained.

In each of the techniques described above, the curing is preferably carried out by transporting the layer of the curable resin composition in a reactor in the manner proper for a roll process to efficiently produce a large-scale molded product.

(Mold Release Process)

The molded product is released from the master mold after the curing process to obtain a resist film in which the convex-concave pattern has been formed in the surface of the cured layer of the curable resin composition by the transfer of the concave-convex pattern of the master mold. In order to suppress deformation of the substrate, such as bending, and enhance the precision of the convex-concave pattern, the release process is preferably carried out after the temperature of the nanoimprint-lithographic molded product is decreased to around normal temperature (25° C.); alternatively, even in the case where the nanoimprint-lithographic molded product holding heat is released, the temperature is preferably decreased to around normal temperature (25° C.) in a state in which a certain level of tension is applied to the nanoimprint-lithographic molded product.

[Dry Etching Resist]

A laminate including a resist film having the pattern formed by the above-mentioned technique can be dry-etched to properly form the pattern on the substrate, so that a patterned product in which the pattern has been formed on the substrate by dry etching can be produced.

In the present invention, since the resist film formed of a dry-etching material exhibits excellent dry etching resistance, the pattern or another part is not damaged during the etching, and thus a precise etching pattern can be provided. Hence, the pattern formed in the resist can be precisely transferred to the substrate, which leads to production of a patterned product exhibiting excellent pattern reproducibility.

Well-known gas can be used in the dry etching. Examples thereof include oxygen atom-containing gases such as an oxygen gas, a carbon monoxide gas, and a carbon dioxide gas; inert gases such as a helium gas, a nitrogen gas, and an argon gas; chlorine-based gases such as a chlorine gas and boron chloride; and fluorine-based gases, a hydrogen gas, and an ammonium gas. These gases may be used alone or appropriately mixed.

Etching with such an etching gas enables formation of an intended pattern on the substrate.

[Wet Etching Resist]

A laminate including a resist film having the pattern formed by the above-mentioned technique can be also wet-etched to properly form the pattern on the substrate, so that a patterned product in which the pattern has been formed on the substrate by wet etching can be produced.

Since the nanoimprint curable composition of the present invention exhibits excellent acid resistance, the pattern or another part is not damaged during the wet etching, and thus a precise etching pattern can be provided. Well-known etchants can be used in the wet etching. Examples thereof include strong alkalis and strong acids (e.g., cupric chloride, ferric chloride, a solution of copper ammonia complex, a solution of sulfuric acid/hydrogen peroxide, ammonium persulfate, hydrofluoric acid, sulfuric acid, ammonium fluoride, and aqueous solution of sulfuric acid/hydrofluoric acid.

In order to produce a patterned product by wet etching, etching is carried out until the resist film is completely removed. In the case where the wet etching is finished in a state in which the resist film is remaining, the remaining film may be removed with an etching gas such as oxygen plasma.

In the nanoimprint curable resin composition of the present invention, the acid value of the vinyl polymer segment (a2) is changed to adjust the total acid value of the composite resin (A) to be in the range of 30 to 400 KOHmg/g, which enables alkali washing.

The alkaline washing solution used in the alkali washing can be appropriately selected from well-known alkaline washing solutions on the basis of intended use and types of the substrate provided that the present invention is not impaired. Examples of the alkaline washing solution include aqueous solutions of sodium hydroxide, potassium hydroxide, and tetramethylammonium hydroxide.

[Resin Mold as Nanoimprint-Lithographic Molded Product]

The nanoimprint-lithographic molded product of the present invention can also be used as a resin mold. The resin mold serves as a template used for further reproducing the nanoimprint-lithographic molded product that has been produced, and a mold formed by transfer from such a resin mold is referred to as a replica mold.

In general, the original template referred to as a master mold is produced. The master mold can be used to directly produce resin molded products; alternatively, a metal mold is produced by transfer from the master mold, and then resin molded products can be formed.

The master mold used as the original template is made of quartz or silicon by, for instance, electron beam lithography, and it is known that production thereof is expensive. In particular, in nanoimprint master molds having nano-order fine patterns, it takes a very long time to form the fine patterns in addition to high production costs.

Especially in production of a metal replica mold with the master mold, the master mold needs to be broken to retrieve the replica mold after metal plating, which has been problematic in terms of production costs. In addition, in the case where a resin molded product is formed as a replica mold, insufficient release thereof from the master mold damages and deforms the fine pattern of the master mold, which causes problems in the subsequent transfer.

In the present invention, however, a resin mold that is the nanoimprint-lithographic molded product can be provided, and a replica mold formed with the resin mold can be provided, the resin mold enabling transfer of a pattern which has a nano-order size and being well released from a master mold and the replica mold.

(Resin Mold)

A pattern of the master mold is transferred to the curable resin composition of the present invention, and then the composition can be cured to produce a resin mold that is the nanoimprint-lithographic molded product of the present invention.

The resin mold can be produced as follows: the master mold is pressed against a coating film formed by applying the nanoimprint curable resin composition onto a substrate, the coating film is cured in this state, and then the coating film cured into the resin mold is released from the master mold.

The resin mold may be produced as follows: the nanoimprint curable resin composition is directly applied to the master mold, a substrate is attached thereto, and then the product is cured in this state.

[(1) Process of Forming Coating Film]

Well-known techniques may be used in the process of forming a coating film in which the nanoimprint curable resin composition is in close contact with a substrate; for example, the nanoimprint curable resin composition that is in the form of a liquid can be applied onto a surface of the substrate to form the coating film. In the case of using the nanoimprint curable resin composition that is in the form of a liquid, the total solid content concentration in the nanoimprint curable resin composition is preferably from 0.1 mass % to 10 mass %, more preferably 0.4 mass % to 5 mass %, and further preferably 0.7 mass % to 2 mass % in view of coating properties (e.g., enabling the thickness of a film to be within an intended range after application of the composition and removal of the solvent, enabling such a thickness to be uniform on the entire target surface, and enabling a coating film having a uniform thickness to be formed so as to cover some unevenness of a target surface). In particular, the thickness of the coating film may be adjusted to be in the range of 10 nm to 50 μm, and more preferably 50 nm to 5 μm.

Organic solvents used for known curable resin compositions may be employed as the solvent. Examples thereof include aliphatic or alicyclic hydrocarbons such as n-hexane, n-heptane, n-octane, cyclohexane, and cyclopentane; aromatic hydrocarbons such as toluene, xylene, and ethylbenzene; alcohols such as methanol, ethanol, n-butanol, ethylene glycol monomethyl ether, and propylene glycol monomethyl ether; esters such as ethyl acetate, n-butyl acetate, isobutyl acetate, n-amyl acetate, ethylene glycol monomethyl ether acetate, and propylene glycol monomethyl ether acetate; ketones such as acetone, methyl ethyl ketone, methyl isobutyl ketone, methyl n-amyl ketone, and cyclohexanone; polyalkylene glycol dialkyl ethers such as diethylene glycol dimethyl ether and diethylene glycol dibutyl ether; ethers such as 1,2-dimethoxyethane, tetrahydrofuran, and dioxane; and N-methylpyrrolidone, dimethylformamide, dimethylacetamide, and ethylene carbonate. These organic solvents can be used alone or in combination.

The coating film of the nanoimprint curable resin composition of the present invention can be formed by forming the nanoimprint curable resin composition of the present invention into a film by known forming techniques such as an extrusion technique; alternatively, the film may be laminated by being thermally press-bonded to a surface of a target product as follows: the nanoimprint curable resin composition is applied to a temporal support film and then dried, and the surface of the applied nanoimprint curable resin composition is optionally covered with a film. Examples of the temporal support film to be used include well-known films such as a polyethylene terephthalate film, a polyimide film, a polyamide-imide film, a polypropylene film, and a polystyrene film. In the case where such a temporal support film has properties necessary for formation of resist films, such as solvent resistance or thermal resistance, the nanoimprint curable resin composition of the present invention can be directly applied onto the temporal support film and then dried to form a coating film. Even in the case where the temporal support film has a low solvent resistance or low thermal resistance, the nanoimprint curable resin composition of the present invention is preliminarily applied onto a film having mold release properties, such as a polytetrafluoroethylene film or a mold release film, the temporal support film having a low solvent resistance and low thermal resistance is subsequently laminated thereon, and then the film having mold release properties is removed to form a coating film of the nanoimprint curable resin composition.

The coating film of the nanoimprint curable resin composition of the present invention may be formed by applying the nanoimprint curable resin composition of the present invention onto a surface of a target product and then removing a solvent by evaporation thereof. Examples of an application technique include spraying, spin coating, dipping, roll coating, blade coating, doctor rolling, doctor blading, curtain coating, slit coating, and screen printing. Spin coating is preferably employed because it enables high productivity and easy control of the thickness of a film.

The substrate used for the resin mold of the present invention is appropriately selected on the basis of intended use of the resin mold of the present invention. Examples of the substrate include quartz substrates; sapphire substrates; glass substrates; optical films; substrates formed of ceramic materials; vapor deposited films; magnetic films; reflection films; substrates formed of metal such as Al, Ni, Cu, Cr, Fe, and stainless steel; screen mesh; paper; wood; substrates made of synthetic resins such as silicone; SOG (Spin On Glass); polymer substrates such as a polyester film, a polycarbonate film, and a polyimide film; TFT array substrates; light emitting diode (LED) substrates such as a sapphire substrate and a GaN substrate; glass substrates and transparent plastic substrates; conducive substrates formed of, for example, indium tin oxide (ITO) and metal; insulating substrates; and substrates used for forming semiconductor devices, such as a silicon substrate, a silicon nitride substrate, a polysilicon substrate, a silicon oxide substrate, and an amorphous silicon substrate. These substrates may transmit light or may not transmit light. The substrate may be in any form on the basis of intended use, such as a plate, a sheet, or a product having an entirely or partially curved three-dimensional geometry. Furthermore, the substrate may have any hardness and thickness.

[(2) Process of Forming Resin Mold]

In a process of pressing the master mold against the coating film of the nanoimprint curable resin composition formed as described above, in particular, the layer of the nanoimprint curable resin composition is allowed to intrude into the fine pattern of the master mold while the master mold is pressed. In this case, in order to further transfer the fine pattern of the master mold to the nanoimprint curable resin composition, the master mold may be pressed while heating is carried out to decrease the viscosity. Then, the layer of the nanoimprint curable resin composition is cured by being irradiated with an active energy ray, and the master mold is subsequently separated to obtain the resin mold in which the fine pattern of the master mold has been formed in the surface of the nanoimprint curable resin composition.

In particular, a master mold is brought into contact with the layer of the nanoimprint curable composition, which has been formed on the surface of the substrate; in this case, the master mold is pressed against the layer of the nanoimprint curable composition such that the layer is pinched. In order to efficiently form a large-scale molded product, the master mold is also preferably brought into contact with the layer of the nanoimprint curable composition by the following techniques: a technique which is suitable for a roll process and in which a planar original plate moves up and down, a bonding technique which involves use of a belt-like original plate, a roll transfer technique which involves use of a roller-like original plate, and a roll transfer technique which involves use of roller-belt-like original plate. Examples of the material used for the master mold include light-transmitting materials, e.g., quartz glass, ultraviolet-transmitting glass, sapphire, diamond, silicon materials such as polydimethylsiloxane, fluororesin, and other light-transmitting materials composed of resins. If the substrate to be used is formed of a light-transmitting material, the master mold may be formed of a material which does not transmit light. Examples of the material which does not transmit light include metal, silicon, Sic, and mica.

As described above, the master mold to be used can be in any form such as a plate, belt, roller, or roller belt. In order to prevent the original plate from being polluted by, for instance, floating dust, the transfer surface is preferably subjected to well-known mold release treatments.

The curing is, for example, carried out by irradiation with light from the master mold side in the case where the master mold is formed of a light-transmitting material or by irradiation with light from the substrate side in the case where the substrate is formed of a light-transmitting material. In the case where both the mold and substrate are formed of light-transmitting materials, light may be emitted from both sides. Any type of light which induces the reaction of the photopolymerization initiator can be emitted; in particular, light having a wavelength of not more than 450 nm (e.g., an active energy ray such as ultraviolet ray, X-ray, or γ-ray) is preferably used because it easily induces the reaction of the photopolymerization initiator and enables curing at lower temperature. In terms of the convenience of operation, light having a wavelength of 200 to 450 nm is especially preferably employed. In particular, light used for the above-mentioned ultraviolet curing can be employed.

In the case where the concave-convex structure of a coating film is not sufficiently transferred to a coating film, heating may be carried out during irradiation with light to a temperature which enables development of sufficient flowability. The temperature in the heating is preferably not more than 300° C., more preferably 0° C. to 200° C., further preferably 0° C. to 150° C., and especially preferably 25° C. to 80° C. Within such a temperature range, the precision of the fine pattern formed in the layer of the nanoimprint curable resin composition is highly maintained.

In each of the techniques described above, the curing is preferably carried out by transporting the layer of the curable resin composition in a reactor in the manner proper for a roll process to efficiently produce a large-scale molded product.

(Mold Release Process)

The resin mold is released from the master mold after the curing process to obtain a resin mold in which a convex-concave pattern has been formed in the surface of the cured layer of the nanoimprint curable resin composition by the transfer of the concave-convex pattern of the mold. In order to suppress deformation of the substrate, such as bending, and enhance the precision of the convex-concave pattern, the release process is preferably carried out after the temperature of the resin mold is decreased to around normal temperature (25° C.); alternatively, even in the case where the resin mold holding heat is released, the temperature is preferably decreased to around normal temperature (25° C.) in a state in which a certain level of tension is applied to the resin mold.

(Replica Mold)

The replica mold can be produced with the resin mold of the present invention which serves as a template. Examples of the replica mold include a metal mold formed of, for instance, nickel and a resin molded product formed of a resin composition.

(Metal Mold)

A metal mold can be produced with the resin mold which has been produced with the master mold, which enables production of the metal mold without damage of the master mold. The same master mold can be used to produce a plurality of metal molds, which leads to simultaneous use of metal molds having the same structure. Hence, molding can be carried out with further enhanced throughput.

((3) Process of Forming Metal Layer)

In order to produce the metal mold of the present invention, a metal layer is formed on the surface of the resin mold, and then the resin mold is released from the metal layer.

The metal layer can be formed by well-known techniques, and the following process can be generally employed:

(3-1) forming a conductive layer on the surface of the resin mold; and

(3-2) laminating the metal layer on the surface of the conductive layer by electroforming.

(3-1) Forming Conductive Layer on Surface of Resin Mold

Examples of a technique for forming a conductive layer include a physical vapor deposition method and electroless plating. Examples of the physical vapor deposition method include sputtering, vacuum evaporation, and ion plating. In the electroless plating, metal fine particles, colloid, and organometallic complexes can be used as a catalyst, and salts of, for example, nickel, copper, cobalt, gold, platinum, and silver can be used as a electroless plating solution.

(3-2) Laminating Metal Layer on Surface of Conductive Layer by Electroforming

The resin mold having the surface on which the conductive layer has been formed is immersed into an electroplating solution, and electricity is applied thereto to deposit metal on the conductive layer, thereby forming a metal layer. Examples of metal used for forming the metal layer include nickel, copper, chromium, aluminum, titanium, tungsten, molybdenum, platinum, and alloys thereof.

((4) Process of Separating Resin Mold to Obtain Metal Mold)

The resin mold above which the metal layer has been laminated through the above-mentioned process is removed at the boundary between the resin mold and the conductive layer to separate the metal layer, thereby yielding a metal mold.

Since the resin mold produced by curing the nanoimprint curable resin composition of the present invention has excellent release properties, the fine pattern thereof is less likely to be damaged and deformed in the separation from the metal mold; hence, the resin mold can be used to produce a replica mold again. In the case where the film remains on the replica mold due to, for instance, the shape of the fine pattern and types of metal, the acid value of the composite resin (A) contained in the nanoimprint curable resin composition is adjusted to be from 30 to 400 KOHmg/g, which enables alkali washing.

The metal mold of the present invention can be used as a template to further carry out imprint on the resin composition, thereby producing a resin molded product that is a tertiary molded product. Well-known resin composition may be used; thermosetting resins, thermoplastic resins, and photocurable resins which will all be described later can be used.

(Resin Molded Product)

The replica mold of the present invention may be a resin molded product.

On the resin mold of the present invention, (5) a second resin layer is formed and then cured, and (6) the resin mold is subsequently separated, thereby yielding a resin molded product to which the fine pattern has been transferred.

The resin molded product may be used as a second resin mold or may be directly used as a final product.

Any resin can be used for forming the second resin layer provided that the effects of the present invention are not impaired, and examples thereof include thermosetting resins, thermoplastic resins, and photocurable resins.

Examples of the thermosetting resins include a phenolic resin, a urea resin, a melamine resin, a furan resin, an alkyd resin, an unsaturated polyester resin, a diallyl phthalate resin, an epoxy resin, a silicone resin, a polyimide resin, a polyurethane resin, and a guanamine resin. Examples of the thermoplastic resins include polyolefin resins, polystyrene resins, a polyvinylchloride resin, a polyvinylidene chloride resin, polyacrylonitrile resins, polyamide resins, polyether imide, polyamide imide, polyester resins, polycarbonate resins, polyacetal resins, a vinyl acetate resin, polyvinyl acetal, a thermoplastic polyurethane elastomer, acrylic resins, polyphenylene resins, a fluororesin, polyvinyl alcohol, polyvinyl pyrrolidone, cellulose derivatives, a phenolic resin, a urea resin, a melamine resin, a furan resin, an alkyd resin, an unsaturated polyester resin, a diallyl phthalate resin, an epoxy resin, a silicone resin, a polyimide resin, a polyurethane resin, and a guanamine resin.

The photocurable resins may be, for example, ultraviolet curable resins or electron beam-curable resins. A variety of known ultraviolet curable resins or electron beam-curable resins can be used, such as acrylic resins, silicone resins, and ester resins. Representative examples thereof include ultraviolet curable resins containing acryloyl groups in their molecules: mixtures of oligomers and polymers composed of epoxy acrylate, urethane acrylate, polyester acrylate, or polyol acrylate with mono-, bi-, or poly-functional polymerizable (meth)acrylic monomers, such as mixtures of monomers, oligomers, polymers of tetrahydrofurfuryl acrylate, 2-hydroxyethyl acrylate, 2-hydroxy-3-phenoxy propylacrylate, polyethylene glycol diacrylate, polypropylene glycol diacrylate, trimethylolpropane triacrylate, pentaerythritol triacrylate, and pentaerythritol tetraacrylate. The photocurable resins may contain photopolymerization initiators or other materials generally used.

These resins may be used alone or in combination at the same time.

(5) Process of Forming and Curing Second Resin Layer

In the formation and curing of the second resin layer, the resin mold may be pressed against the second resin layer formed on a substrate prepared for forming the second resin layer and then cured.

Alternatively, a resin used for forming the second resin layer may be directly applied to the resin mold, the substrate may be subsequently bonded thereto, and then curing may be carried out in this state.

The resin used for forming the second resin layer may appropriately contain a variety of additives such as an organic solvent, an inorganic pigment, an organic pigment, an extender pigment, clay minerals, wax, a surfactant, a stabilizer, a flow modifier, a dye, a leveling agent, a rheology control agent, a UV absorber, an antioxidant, and a plasticizer. Furthermore, an adhesion enhancer composed of a silane coupling agent; inorganic fine particles such as talc, mica, clay, silica, alumina, sericite, white carbon, gypsum, isinglass, barium sulfate, barium carbonate, and magnesium carbonate; coloring materials such as pigments and dyes; and coating additives such as a discoloration inhibitor, an antioxidant, a UV absorber, a plasticizer, and a lubricant may be used.

(6) Process of Separating Resin Mold and Obtaining Resin Molded Product

After the second resin layer is cured in Process (5) in a state in which the resin mold is pressed against the second resin layer, the resin mold is separated from the cured second resin layer, so that a resin molded product that is a replica mold to which the fine pattern of the resin mold has been transferred can be yielded. The resin molded product may be directly used as the final product or may be further used as a mold.

### EXAMPLES

The present invention will now be specifically described with reference to Examples and Comparative Examples. In Examples, the terms “part” and “%” are on a weight basis unless otherwise specified.

### Synthesis Example 1

### Example of Preparation of Polysiloxane (a1-1)

Into a reaction vessel having a stirrer, a thermometer, a dropping funnel, a cooling pipe, and a nitrogen gas inlet, 415 parts of methyltrimethoxysilane (MTMS) and 756 parts of 3-methacryloyloxypropyltrimethoxysilane (MPTS) were put, and the temperature was increased to 60° C. under the flow of a nitrogen gas while the contents were stirred. Then, the mixture of 0.1 part of “Phoslex A-3” [isopropyl acid phosphate manufactured by Sakai Chemical Industry Co., Ltd.] and 121 parts of deionized water was added dropwise thereto for 5 minutes. After the addition of the mixture, the temperature inside the reaction vessel was increased to 80° C., and then the contents were stirred for 4 hours to induce a hydrolysis and condensation reaction, thereby producing a reaction product.

Methanol and water contained in the reaction product were removed under a reduced pressure of 1 to 30 kilopascals (kPa) at 40 to 60° C. to yield 1000 parts of polysiloxane (a1-1) having a number-average molecular weight of 1000 and containing an active ingredient of 75.0%.

The term “active ingredient” refers to a value obtained by dividing a theoretical yield (parts by weight) based on the assumption that all of the methoxy groups contained in silane monomers used have been subjected to a hydrolysis and condensation reaction by the actual yield (parts by weight) after the hydrolysis and condensation reaction; in other words, the active ingredient can be calculated from the formula [theoretical yield (parts by weight) based on the assumption that all of the methoxy groups contained in silane monomers have been subjected to a hydrolysis and condensation reaction/actual yield (parts by weight) after the hydrolysis and condensation reaction].

### Synthesis Example 2

### Example of Preparation of Polysiloxane (a1-2)

Into the same reaction vessel as used in Synthesis Example 1, 442 parts of MTMS and 760 parts of 3-acryloyloxypropyltrimethoxysilane (APTS) were put, and the temperature was increased to 60° C. under the flow of a nitrogen gas while the contents were stirred. Then, the mixture of 0.1 part of “Phoslex A-3” and 129 parts of deionized water was added dropwise thereto for 5 minutes. After the addition of the mixture, the temperature inside the reaction vessel was increased to 80° C., and then the contents were stirred for 4 hours to induce a hydrolysis and condensation reaction, thereby producing a reaction product. Methanol and water contained in the reaction product were removed under a reduced pressure of 1 to 30 kilopascals (kPa) at 40 to 60° C. to yield 1000 parts of polysiloxane (a1-2) having a number-average molecular weight of 1000 and containing an active ingredient of 75.0%.

### Synthesis Example 3

### Example of Preparation of Vinyl Monomer (a2-1)

Into the same reaction vessel as used in Synthesis Example 1, 20.1 parts of phenyltrimethoxysilane (PTMS), 24.4 parts of dimethyldimethoxysilane (DMDMS), and 107.7 parts of n-butyl acetate were put, and the temperature was increased to 80° C. under the flow of a nitrogen gas while the contents were stirred. Then, a mixture containing 15 parts of methyl methacrylate (MMA), 45 parts of n-butyl methacrylate (BMA), 39 parts of 2-ethylhexyl methacrylate (EHMA), 1.5 parts of acrylic acid (AA), 4.5 parts of MPTS, 45 parts of 2-hydroxyethyl methacrylate (HEMA), 15 parts of n-butyl acetate, and 15 parts of tert-butylperoxy-2-ethylhexanoate (TBPEH) was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a vinyl polymer (a2-1) that was a reaction product containing a TBPEH residue of not more than 0.1%.

### Synthesis Example 4

### Example of Preparation of Vinyl Monomer (a2-2)

Into the same reaction vessel as used in Synthesis Example 1, 20.1 parts of phenyltrimethoxysilane (PTMS), 24.4 parts of dimethyldimethoxysilane (DMDMS), and 107.7 parts of n-butyl acetate were put, and the temperature was increased to 80° C. under the flow of a nitrogen gas while the contents were stirred. Then, a mixture containing 14.5 parts of methyl methacrylate (MMA), 2 parts of n-butyl methacrylate (BMA), 105 parts of cyclohexyl methacrylate (CHMA), 7.5 parts of acrylic acid (AA), 4.5 parts of MPTS, 15 parts of 2-hydroxyethyl methacrylate (HEMA), 15 parts of n-butyl acetate, and 6 parts of tert-butylperoxy-2-ethylhexanoate (TBPEH) was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a vinyl polymer (a2-2) that was a reaction product containing a TBPEH residue of not more than 0.1%.

### Synthesis Example 5

### Example of Preparation of Vinyl Monomer (a2-3)

Into the same reaction vessel as used in Synthesis Example 1, 20.1 parts of phenyltrimethoxysilane (PTMS), 24.4 parts of dimethyldimethoxysilane (DMDMS), and 107.7 parts of n-butyl acetate were put, and the temperature was increased to 80° C. under the flow of a nitrogen gas while the contents were stirred. Then, a mixture containing 15 parts of methyl methacrylate (MMA), 45 parts of n-butyl methacrylate (BMA), 39 parts of 2-ethylhexyl methacrylate (EHMA), 1.5 parts of acrylic acid (AA), 4.5 parts of MPTS, 45 parts of 2-hydroxyethyl methacrylate (HEMA), 15 parts of n-butyl acetate, and 15 parts of tert-butylperoxy-2-ethylhexanoate (TBPEH) was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a vinyl polymer (a2-3) that was a reaction product containing a TBPEH residue of not more than 0:1%.

### Synthesis Example 6

### Example of Preparation of Composite Resin (A-1)

Into the same reaction vessel as used in Synthesis Example 1, 20.1 parts of phenyltrimethoxysilane (PTMS), 24.4 parts of dimethyldimethoxysilane (DMDMS), and 107.7 parts of n-butyl acetate were put, and the temperature was increased to 80° C. under the flow of a nitrogen gas while the contents were stirred. Then, a mixture containing 15 parts of methyl methacrylate (MMA), 45 parts of n-butyl methacrylate (BMA), 39 parts of 2-ethylhexyl methacrylate (EHMA), 1.5 parts of acrylic acid (AA), 4.5 parts of MPTS, 45 parts of 2-hydroxyethyl methacrylate (HEMA), 15 parts of n-butyl acetate, and 15 parts of tert-butylperoxy-2-ethylhexanoate (TBPEH) was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 162.5 parts of the polysiloxane (a1-1) synthesized in Synthesis Example 1 was added to the reaction product, and the product was stirred for 5 minutes. Then, 27.5 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of methyl ethyl ketone (MEK) and 27.3 parts of n-butyl acetate were added thereto to produce 600 parts of a composite resin (A-1) containing a non-volatile component of 50.0% and having a polysiloxane segment and a vinyl polymer segment.

### Synthesis Example 7

### Example of Preparation of Composite Resin (A-2)

Into the same reaction vessel as used in Synthesis Example 1, 20.1 parts of PTMS, 24.4 parts of DMDMS, and 107.7 parts of n-butyl acetate were put, and the temperature was increased to 80° C. under the flow of a nitrogen gas while the contents were stirred. Then, a mixture containing 15 parts of MMA, 45 parts of BMA, 39 parts of EHMA, 1.5 parts of AA, 4.5 parts of MPTS, 45 parts of HEMA, 15 parts of n-butyl acetate, and 15 parts of TBPEH was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 562.5 parts of the polysiloxane (a1-1) synthesized in Synthesis Example 1 was added to the reaction product, and the product was stirred for 5 minutes. Then, 80.0 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 128.6 parts of MEK and 5.8 parts of n-butyl acetate were added thereto to produce 857 parts of a composite resin (A-2) containing a non-volatile component of 70.0% and having a polysiloxane segment and a vinyl polymer segment.

### Synthesis Example 8

### Example of Preparation of Composite Resin (A-3)

Into the same reaction vessel as used in Synthesis Example 1, 20.1 parts of PTMS, 24.4 parts of DMDMS, and 107.7 parts of n-butyl acetate were put, and the temperature was increased to 80° C. under the flow of a nitrogen gas while the contents were stirred. Then, a mixture containing 15 parts of MMA, 45 parts of BMA, 39 parts of EHMA, 1.5 parts of AA, 4.5 parts of MPTS, 45 parts of HEMA, 15 parts of n-butyl acetate, and 15 parts of TBPEH was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 162.5 parts of the polysiloxane (a1-2) synthesized in Synthesis Example 2 was added to the reaction product, and the product was stirred for 5 minutes. Then, 27.5 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of MEK and 27.3 parts of n-butyl acetate were added thereto to produce 600 parts of a composite resin (A-3) containing a non-volatile component of 50.0% and having a polysiloxane segment and a vinyl polymer segment.

### Synthesis Example 9

### Example of Preparation of Composite Resin (A-4)

Into the same reaction vessel as used in Synthesis Example 1, 17.6 parts of PTMS, 21.3 parts of DMDMS, and 129.0 parts of n-butyl acetate were put, and the temperature was increased to 80° C. under the flow of a nitrogen gas while the contents were stirred. Then, a mixture containing 21 parts of MMA, 63 parts of BMA, 54.6 parts of EHMA, 2.1 parts of AA, 6.3 parts of MPTS, 63 parts of HEMA, 21 parts of n-butyl acetate, and 21 parts of TBPEH was dropped into the reaction vessel for 4 hours at the same temperature under the flow of a nitrogen gas while the contents were stirred. The contents were further stirred for two hours at the same temperature. Then, a mixture of 0.04 parts of “Phoslex A-3” and 11.2 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the trimethoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 87.3 parts of the polysiloxane (a1-1) synthesized in Synthesis Example 1 was added to the reaction product, and the product was stirred for 5 minutes. Then, 12.6 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of MEK was added thereto to produce 600 parts of a composite resin (A-4) containing a non-volatile component of 50.0% and having a polysiloxane segment and a vinyl polymer segment.

### Synthesis Example 10

### Example of Preparation of Composite Resin (A-5)

To 346 parts of the vinyl polymer (a2-1) synthesized in Synthesis Example 3, 148 parts of n-butyl methacrylate was added, 162.5 parts of the polysiloxane (a1-1) synthesized in Synthesis Example 1 was subsequently added thereto, and then the product was stirred for 5 minutes. Then, 27.5 parts of deionized water was added thereto, and the product was stirred for 4 hours at 80° C. to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction, thereby yielding 400 parts of a composite resin (A-5) containing a non-volatile component of 72% and having a polysiloxane segment (a1-1) and a vinyl polymer segment (a2-1).

### Synthesis Example 11

### Example of Preparation of Composite Resin (A-6)

To 307 parts of the vinyl polymer (a2-1) synthesized in Synthesis Example 3, 162.5 parts of the polysiloxane (a1-1) synthesized in Synthesis Example 1 was added, and then the product was stirred for 5 minutes. Then, 27.5 parts of deionized water was added thereto, and the product was stirred for 4 hours at 80° C. to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of methyl ethyl ketone (MEK) and 27.3 parts of n-butyl acetate were added thereto to produce 600 parts of a composite resin (A-6) containing a non-volatile component of 50.0% and having a polysiloxane segment (a1-1) and a vinyl polymer segment (a2-1).

### Synthesis Example 12

### Example of Preparation of Composite Resin (A-7)

To 307 parts of the vinyl polymer (a2-2) synthesized in Synthesis Example 3, 162.5 parts of the polysiloxane (a1-1) synthesized in Synthesis Example 1 was added, and then the product was stirred for 5 minutes. Then, 27.5 parts of deionized water was added thereto, and the product was stirred for 4 hours at 80° C. to induce the hydrolysis and Condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of methyl ethyl ketone (MEK) and 27.3 parts of n-butyl acetate were added thereto to produce 600 parts of a composite resin (A-7) containing a non-volatile component of 50.0% and having a polysiloxane segment (a1-1) and a vinyl polymer segment (a2-2).

### Synthesis Example 13

### Example of Preparation of Composite Resin (A-8)

To 307 parts of the vinyl polymer (a2-3) synthesized in Synthesis Example 5, 162.5 parts of the polysiloxane (a1-1) synthesized in Synthesis Example 1 was added, and then the product was stirred for 5 minutes. Then, 27.5 parts of deionized water was added thereto, and the product was stirred for 4 hours at 80° C. to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of methyl ethyl ketone (MEK) and 27.3 parts of n-butyl acetate were added thereto to produce 600 parts of a composite resin (A-8) containing a non-volatile component of 50.0% and having a polysiloxane segment (a1-1) and a vinyl polymer segment (a2-3).

### Synthesis Example 14

### Example of Preparation of Composite Resin (A-9)

Into the same reaction vessel as used in Synthesis Example 1, 20.1 parts of phenyltrimethoxysilane (PTMS), 24.4 parts of dimethyldimethoxysilane (DMDMS), and 106.4 parts of n-butyl acetate were put, and the temperature was increased to 95° C. under the flow of a nitrogen gas while the contents were stirred. Then, a mixture containing 105.8 parts of methyl methacrylate (MMA), 19.7 parts of n-butyl acrylate (BA), 19.3 parts of acrylic acid (AA), 4.5 parts of MPTS, 0.8 parts of 2-hydroxyethyl methacrylate (HEMA), 15 parts of n-butyl acetate, and 15 parts of tert-butylperoxy-2-ethylhexanoate (TBPEH) was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the methoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 162.5 parts of the polysiloxane (a1-1) synthesized in Synthesis Example 1 was added to the reaction product, and the product was stirred for 5 minutes. Then, 27.5 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 150 parts of methyl ethyl ketone (MEK) and 28.6 parts of n-butyl acetate were added thereto to produce 600 parts of a composite resin (A-9) containing a non-volatile component of 50.0% and having a polysiloxane segment and a vinyl polymer segment.

The acid value [milligrams (mg) of potassium hydroxide necessary for neutralization of acid components contained in 1 g of a sample] of the composite resin (A-9) was measured by an indicator titration method using phenolphthalein in accordance with JIS K 2501-2003. The acid value of the composite resin (A-9) was 50.2 KOHmg/g on a solid content basis.

### Synthesis Example 15

### Example of Preparation of Composite Resin (A-10)

Into the same reaction vessel as used in Synthesis Example 1, 20.1 parts of PTMS, 24.4 parts of DMDMS, and 107.7 parts of n-butyl acetate were put, and the temperature was increased to 95° C. under the flow of a nitrogen gas while the contents were stirred. Then, a mixture containing 66.4 parts of MMA, 1.2 parts of BA, 77.1 parts of AA, 4.5 parts of MPTS, 0.8 parts of HEMA, 15 parts of n-butyl acetate, and 15 parts of TBPEH was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 12.8 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the methoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 562.5 parts of the polysiloxane (a1-1) synthesized in Synthesis Example 1 was added to the reaction product, and the product was stirred for 5 minutes. Then, 80.0°parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 128.6 parts of MEK and 5.9 parts of n-butyl acetate were added thereto to produce 857 parts of a composite resin (A-10) containing a non-volatile component of 70.0% and having a polysiloxane segment and a vinyl polymer segment.

The acid value of the composite resin (A-10) was measured by an indicator titration method using phenolphthalein in accordance with JIS K 2501-2003. The acid value of the composite resin (A-10) was 100.2 KOHmg/g on a solid content basis.

### Synthesis Example 16

### Example of Preparation of Composite Resin (A-11)

Into the same reaction vessel as used in Synthesis Example 1, 5.0 parts of PTMS, 6.1 parts of DMDMS, and 107.7 parts of n-butyl acetate were put, and the temperature was increased to 95° C. under the flow of a nitrogen gas while the contents were stirred. Then, a mixture containing 57.8 parts of MMA, 0.4 parts of BA, 86.6 parts of AA, 4.5 parts of MPTS, 0.8 parts of HEMA, 15 parts of n-butyl acetate, and 15 parts of TBPEH was dropped into the reaction vessel for 4 hours at the same temperature under the flow of a nitrogen gas while the contents were stirred. The contents were further stirred for two hours at the same temperature. Then, a mixture of 0.05 parts of “Phoslex A-3” and 3.2 parts of deionized water was dropped into the reaction vessel for 5 minutes, and the contents were stirred for 4 hours at the same temperature to promote a hydrolysis and condensation reaction of PTMS, DMDMS, and MPTS. The reaction product was analyzed by ¹H-NMR, and the result of the analysis showed that substantially 100% of the methoxysilyl groups contained in the silane monomers in the reaction vessel had been subjected to the hydrolysis. Then, the product was stirred for 10 hours at the same temperature to yield a reaction product containing a TBPEH residue of not more than 0.1%. In this case, the TBPEH residue was measured by an iodometric titration method.

Then, 40.6 parts of the polysiloxane (a1-2) synthesized in Synthesis Example 2 was added to the reaction product, and the product was stirred for 5 minutes. Then, 10.2 parts of deionized water was added thereto, and the product was stirred at 80° C. for 4 hours to induce the hydrolysis and condensation reaction of the reaction product with the polysiloxane. This resulting product was distilled for 2 hours under a reduced pressure of 10 to 300 kPa at 40 to 60° C. to remove methanol and water which had been generated in the reaction. Then, 37.5 parts of MEK and 27.3 parts of n-butyl acetate were added thereto to produce 375.0 parts of a composite resin (A-11) containing a non-volatile component of 50.0% and having a polysiloxane segment and a vinyl polymer segment.

The acid value of the composite resin (A-11) was measured by an indicator titration method using phenolphthalein in accordance with JIS K 2501-2003. The acid value of the composite resin (A-11) was 360.4 KOHmg/g on a solid content basis.

### Synthesis Example 17

### Example of Preparation of Composite Resin (A-12)

Into the same reaction vessel as used in Synthesis Example 1, 20.1 parts of PTMS, 24.4 parts of DMDMS, and 107.7 parts of n-butyl acetate were put, and the temperature was increased to 95° C. under the flow of a nitrogen gas while the contents were stirred. Then, a mixture containing 53.1 parts of MMA, 1.6 parts of BA, 90.0 parts of AA, 4.5 parts of MPTS, 0.8 parts of HEMA, 15 parts of n-butyl acetate, and 15 parts of TBPEH was dropped into the reaction vessel for 4 hours at the same temperature under the flow of a nitrogen gas while the contents were stirred. At the time that the contents had been stirred for an hour at the same temperature, the viscosity of the reaction solution drastically increased, and the reaction solution gelled in several minutes.

The acid value of the vinyl polymer segment of the resin solution which had gelled was estimated as 467.5 KOHmg/g from the AA content.

Although the present invention will now be further specifically described with reference to Examples, the present invention should not be limited thereto.

### Example 1

### Example of Production of Nanoimprint Curable Composition and Resist Film

A nanoimprint curable composition (hereinafter referred to as composition) -1 was prepared by mixing 40.0 parts of the composite resin (A-1) synthesized in Synthesis Example 1, 7.0 parts of pentaerythritol triacrylate (PETA), 1.08 parts of Irgacure 184 [photopolymerization initiator manufactured by Ciba Japan K.K.], 0.67 parts of Tinuvin 400 [ultraviolet absorber composed of hydroxyphenyltriazine, manufactured by Ciba Japan K.K.], and 0.34 parts of Tinuvin 123 [light stabilizer composed of hindered amine (HALS), manufactured by Ciba Japan K.K.].

Then, the composition-1 was applied onto a sapphire substrate, and a planar mold formed of quartz glass and having the structure that was in the form of a line and, space with a width of 200 nm, a pitch of 200 nm, and a height of 200 nm was pressed against the surface of the composition-1. In this state, light was emitted from the resin composition side at a light intensity of 1000 mJ/cm² with an LED light source (manufactured by IMAC Co., Ltd.) exhibiting the peak wavelength of 375 nm±5 to cure the composition-1. Then, the mold and the sapphire substrate were removed to yield a resist film (1) having a pattern that was in the form of a line and space.

### Examples 2 to 5

As in Example 1, (composition-2) to (composition-5) were produced as nanoimprint curable compositions as shown in Table 1.

Resist films (2) to (5) having a pattern that was in the form of a line and space were produced as in Example 1.

### Comparative Example 1

As in Example 1, a comparative nanoimprint curable composition (comparative composition-1) was produced as shown in Table 2. A comparative resist film (H1) having a pattern that was in the form of a line and space was produced as in Example 1.

(Evaluation)

The resist films (1) to (5) produced in Examples 1 to 5 and the comparative resist film (H1) produced in Comparative Example 1 were evaluated as follows.

(Evaluation of Pattern Formation)

The pattern of each resist film was analyzed with a scanning microscopy (JSM-7500F manufactured by JEOL Ltd.) at 100,000-folds magnification, and result of the analysis was evaluated as follows.

Good: Concave-convex pattern correctly reflected the structure of the mold, in which the top of the pattern had no cracked part such as round part
Acceptable: Concave-convex pattern correctly reflected the structure of the mold, in which the top of the pattern had some cracked parts such as round parts
Bad: Concave-convex pattern did not correctly reflect the structure of the mold, in which the top of the pattern had cracked part such as round part with the result that the line pattern had an arch-shaped structure.

(Evaluation of Pattern-Shape-Holding Properties)

Each resist film was subjected to a treatment with oxygen plasma to remove a residual film. Then, the pattern-shape-holding properties were analyzed with a scanning microscopy (JSM-7500F manufactured by JEOL Ltd.) at 100,000-folds magnification, and result of the analysis was evaluated as follows.

Good: Ratio of the width of the pattern after the removal of the residual film to a mold width of 200 nm was 0.8 or more

Acceptable: Ratio of the width of the pattern after the removal of the residual film to a mold width of 200 nm was 0.5 or more and less than 0.8

Bad: Ratio of the width of the pattern after the removal of the residual film to a mold width of 200 nm was less than 0.5

Tables 1 and 2 show the components of the nanoimprint curable compositions and results of the evaluations of the resist films in Examples 1 to 5 and Comparative Example 1.

TABLE 1

| | | Example 1 | Example 2 | Example 3 | Example 4 | Example 5 |
|---|---|---|---|---|---|---|
| Composite resin | (A-1) | 40 | | | | |
| | (A-2) | | 21.4 | | | |
| | (A-3) | | | 10 | | |
| | (A-4) | | | | 40 | |
| | (A-5) | | | | | 38.7 |
| (a1) content (%) to composite | | 50 | 75 | 50 | 30 | 36.2 |
| resin *2 | | | | | | |
| (a1) content (%) *1 | | 35.2 | 55.1 | 12.8 | 19.0 | 25.4 |
| Polyfunctional | PETA | 7 | 4.4 | | 10 | 9.8 |
| acrylate | | | | | | |
| | 17-813 | | | 16.9 | | |
| Photopolymerization | I-184 | 1.08 | 0.78 | 0.37 | 1.2 | 1.5 |
| initiator | I-127 | | | 0.37 | | |
| Light stabilizer | Tinuvin | 0.34 | 0.23 | | 0.39 | 0.47 |
| (HALS) | 123 | | | | | |
| | Tinuvin | | | 0.2 | | |
| | 152 | | | | | |
| Nanoimprint curable | | Composi- | Composi- | Composi- | Composi- | Composi- |
| composition | | tion-1 | tion-2 | tion-3 | tion-4 | tion-5 |
| Evaluation of Resist | Pattern | Good | Good | Good | Good | Good |
| Film | formation | | | | | |
| | Pattern- | Good | Good | Good | Accept- | Good |
| | shape- | | | | able | |
| | holding | | | | | |
| | properties | | | | | |

TABLE 2

| | | Comparative |
|---|---|---|
| | | Example 1 |
| Composite resin | (A-1) | |
| | (A-2) | |
| | (A-3) | |
| | (A-4) | |
| | (A-5) | |
| (a1) content (%) to composite resin *2 | | 0 |
| (a1) content (%) *1 | | 0 |
| Polyfunctional acrylate | PETA | |
| | 17-813 | 37.5 |
| Photopolymerization | I-184 | 1.2 |
| initiator | I-127 | |
| Light stabilizer | Tinuvin 123 | 0.3 |
| (HALS) | Tinuvin 152 | |
| Nanoimprint curable composition | | Comparative |
| | | Composition-1 |
| Evaluation of Resist Film | Pattern formation | Good |
| | Pattern-shape-holding | Bad |
| | properties | |

The results of the evaluations in Examples 1 to 5 show that resist films (1) to (5) formed of the nanoimprint curable resin compositions (composition-1) to (composition-5) each exhibited excellent pattern formability and pattern-shape-holding properties, respectively.

The comparative resist film (H1) of Comparative Example 1 did not contain the composite resin (A) and thus had poor pattern-shape-holding properties.

### Example 6

### Formation of Dry Etching Resist Film

A nanoimprint curable resin composition-6 (composition-6) used for a dry etching resist film was prepared by mixing 108.5 parts of the composite resin (A-1) synthesized in Synthesis Example 6, 20.2 parts of pentaerythritol triacrylate (PETA), 3.2 parts of Irgacure 184 (photopolymerization initiator manufactured by Ciba Japan K.K.), and 0.74 parts of Tinuvin 123 [light stabilizer composed of hindered amine (HALS), manufactured by Ciba Japan K.K.].

(Example of Formation of Uniform Resist Film)

The composition-6 was applied onto a silicon wafer substrate with a spin coater, and the product was heated on a hot plate at 80° C. for a minute. Then, light was emitted from the resist composition side at a light intensity of 1000 mJ/cm² with an LED light source (manufactured by IMAC Co., Ltd.) exhibiting the peak wavelength of 375 nm±5 to cure a resist film, thereby forming a resist film (6-1) having a uniform thickness of 0.5 μm on the surface of the substrate. In the same manner, a uniform resist film (6-2) was formed on a super white glass substrate, a uniform resist film (6-3) was formed on a quartz glass substrate, and a uniform resist film (6-4) was formed on a surface of a sapphire substrate.

(Production of Patterned Resist Film)

The composition-6 was applied onto a silicon wafer substrate with a spin coater, and the product was heated on a hot plate at 80° C. for a minute. Then, a planar mold formed of quartz glass and having the structure that was in the form of a line and space with a width of 200 nm, a pitch of 200 nm, and a height of 200 nm was pressed against the surface of the composition-6. In this state, light was emitted from the resist composition side at a light intensity of 1000 mJ/cm² with an LED light source (manufactured by IMAC Co., Ltd.) exhibiting the peak wavelength of 375 nm±5 to cure the resin composition-6. Then, the mold and the silicon wafer substrate were removed to yield a resist film (6-5) having a pattern that was in the form of a line and space. In the same manner, a patterned resist film (6-6) was formed on a super white glass substrate, a patterned resist film (6-7) was formed on a quartz glass substrate, and a patterned resist film (6-8) was formed on a sapphire substrate.

### Example 7

As in Example 6, a composition-7 was prepared as shown in Table 1.

As in Example 6, uniform resist films (7-1) to (7-4) and patterned resist films (7-5) to (7-8) were formed.

### Comparative Example 2

As in Example 6, a comparative nanoimprint curable composition used for a resist film (comparative composition-2) was prepared as shown in Table 2.

As in Example 1, comparative uniform resist films (H2-1) to (H2-4) and patterned resist films (H2-5) to (H2-8) were formed.

(Evaluation)

Examples 6 and 7 and Comparative Example 2 were evaluated as follows.

(Dry Etching Resistance)

The resist films (6-1), (6-5), (7-1), (7-5), (H2-1), and (H2-5) formed on silicon wafer substrates were subjected to plasma dry etching for a minute with a desktop series Plasma Etching (manufactured by YOUTEC Co., Ltd.) under a vacuum of 0.8 Pa and the flow of the mixed gas of CF4/02 at flow rates of 40 sccm and 10 sccm, respectively. Then, the thickness of each residual film was analyzed to calculate an etching rate per minute.

The resist films (6-2), (6-6), (7-2), (7-6), (H2-2), and (H2-6) formed on super white glass substrates were subjected to plasma etching for a minute with an EIS-700 manufactured by ELIONIX INC under a vacuum of 0.4 Pa and the flow of the mixed gas of SF6/C4F8 at flow rates of 20 sccm and 5 sccm, respectively. Then, the thickness of each residual film was analyzed to calculate an etching rate per minute.

The resist films (6-3), (6-7), (7-3), (7-7), (H2-3), and (H2-7) formed on quartz glass substrates were subjected to plasma etching for a minute with an EIS-700 manufactured by ELIONIX INC under a vacuum of 0.4 Pa and the flow of the mixed gas of SF6/C4F8 at flow rates of 20 sccm and 5 sccm, respectively. Then, the thickness of each residual film was analyzed to calculate an etching rate per minute.

The resist films (6-4), (6-8), (7-4), (7-8), (H2-4), and (H2-8) formed on sapphire substrates were subjected to plasma etching for a minute with an RIE-101iPH manufactured by SAMCO INC. under a vacuum of 0.7 Pa and the flow of the mixed gas of BCl3/Cl2/Ar at flow rates of 20 sccm, 15 sccm, and 20 sccm, respectively. Then, the thickness of each residual film was analyzed to calculate an etching rate per minute.

The obtained etching rates were normalized such that the etching rate in Comparative Example 1 was 1. The smaller the normalized value is, the more excellent dry etching resistance is. The following evaluation criteria were employed.

Excellent: Normalized etching rate of 0 or more and less than 0.3
Good: Normalized etching rate of 0.3 or more and less than 0.6
Unacceptable: Normalized etching rate of 0.6 or more and less than 1
Bad: Normalized etching rate of 1 or more

(Evaluation of Pattern Reproducibility)

Precision in reproducibility of the patterns of the patterned resist films (6-5) to (6-8), (7-5) to (7-8), and (H2-5) to (H2-8), which had been transferred to the dry-etched substrates, was evaluated as follows.

Good: The pattern had a highly vertical side wall and had a cross-sectional shape that was a good rectangular shape
Bad: The pattern had a non-vertical side wall and had a cross-sectional shape that was not a good rectangular shape

Tables 3 and 4 show the components of the resist compositions and results of the evaluations of the etching rates of the resist films in Examples 6 and 7 and Comparative Example 2.

TABLE 3

| | | | Example 6 | | Example 7 | |
|---|---|---|---|---|---|---|
| Composite resin | | (A-6) | 108.5 | | | |
| | | (A-7) | | | 108.5 | |
| (a1) content (%) to composite resin *2 | | | 50 | | 50 | |
| (a1) content (%) *1 | | | 34.6 | | 34.6 | |
| Polyfunctional acrylate | | PETA | 20.2 | | 20.2 | |
| Photopolymerization initiator | | I-184 | 3.2 | | 3.2 | |
| Light stabilizer (HALS) | | Tinuvin 123 | 0.74 | | 0.74 | |
| Nanoimprint curable composition | | | Composi- | | Composi- | |
| | | | tion-6 | | tion-7 | |
| Dry etching resistance | Uniform resist film | Silicon wafer | (6-1) | Good | (7-1) | Excellent |
| | | substrate | | | | |
| | | Super white glass | (6-2) | Good | (7-2) | Excellent |
| | | Quarts glass | (6-3) | Good | (7-3) | Excellent |
| | | substrate | | | | |
| | | Sapphire substrate | (6-4) | Good | (7-4) | Excellent |
| | Patterned resist | Silicon wafer | (6-5) | Good | (7-5) | Excellent |
| | film | substrate | | | | |
| | | Super white glass | (6-6) | Good | (7-6) | Excellent |
| | | Quarts glass | (6-7) | Good | (7-7) | Excellent |
| | | substrate | | | | |
| | | Sapphire substrate | (6-8) | Good | (7-8) | Excellent |
| Evaluation of pattern | Patterned resist | Silicon wafer | (6-5) | Good | (7-5) | Good |
| reproducibility | film | substrate | | | | |
| | | Super white glass | (6-6) | Good | (7-6) | Good |
| | | Quarts glass | (6-7) | Good | (7-7) | Good |
| | | substrate | | | | |
| | | Sapphire substrate | (6-8) | Good | (7-8) | Good |

TABLE 4

| | | | Comparative | |
|---|---|---|---|---|
| | | | Example 2 | |
| Composite Resin | | (A-1) | | |
| | | (A-2) | | |
| (a1) content (%) to composite resin *2 | | | 0 | |
| (a1) content (%) *1 | | | 0 | |
| Polyfunctional acrylate | | PETA | 75 | |
| Photopolymerization initiator | | I-184 | 3 | |
| Light stabilizer (HALS) | | Tinuvin 123 | 0.74 | |
| Nanoimprint curable composition | | | Comparative | |
| | | | Composition-2 | |
| Dry etching | Uniform | Silicon wafer substrate | (H2-1) | Bad |
| resistance | resist film | Super white glass | (H2-2) | Bad |
| | | Quarts glass substrate | (H2-3) | Bad |
| | | Sapphire substrate | (H2-4) | Bad |
| | Patterned | Silicon wafer substrate | (H2-5) | Bad |
| | resist film | Super white glass | (H2-6) | Bad |
| | | Quarts glass substrate | (H2-7) | Bad |
| | | Sapphire substrate | (H2-8) | Bad |
| Evaluation | Patterned | Silicon wafer substrate | (H2-5) | Bad |
| of pattern | resist film | Super white glass | (H2-6) | Bad |
| reproducibility | | Quarts glass substrate | (H2-7) | Bad |
| | | Sapphire substrate | (H2-8) | Bad |

The results of the evaluations of Example 6 and 7 show that the resist films (6-1) to (6-8) and the resist films (7-1) to (7-8) formed of the nanoimprint curable compositions (composition-6) and (composition-7), respectively, had an excellent dry etching resistance. The resist film formed in Comparative Example 2 did not contain the composite resin (A) and had a poor dry etching resistance.

### Example 8

### Preparation of Resin Mold Composition-1

A nanoimprint curable composition-8 (composition-8) used for producing a resin mold was prepared by mixing 40.0 parts of the composite resin (A-11) synthesized in Synthesis Example 16, 14.7 parts of dipentaerythritol hexaacrylate (DPHA), and 1.39 parts of Irgacure 184 (photopolymerization initiator, manufactured by Ciba Japan K.K.).

(Production of Resin Mold)

The composition-1 was applied onto a silicon wafer substrate with a spin coater, and the product was heated on a hot plate at 80° C. for a minute. Then, a planar master mold formed of quartz glass and having columnar structures arranged into a regular triangular grid and each having a diameter of 230 nm, a height of 200 nm, and a pitch of 460 nm was pressed against the surface of the composition-1. In this state, light was emitted from the master mold side at a light intensity of 300 mJ/cm² with an LED light source (manufactured by IMAC Co., Ltd.) exhibiting the peak wavelength of 375 nm±5 to cure the composition-1. Then, the master mold and the silicon wafer substrate were removed to yield a resin mold-1 having a columnar pattern.

(Example of Production of Metal Mold by Alkali Solution of Resin Mold)

A nickel conductive layer was formed on the surface of the columnar pattern-formed surface of the resin mold by sputtering. Then, the resin mold on which the conductive layer had been formed was immersed into a nickel electroforming bath, which contained the following components, for an electroforming treatment. Then, the product was immersed into an aqueous solution of 20 wt % potassium hydroxide at 30° C. for 300 seconds to remove the resin mold from the nickel layer by dissolution thereof, thereby yielding a metal mold 1-1.

(Example of Production of Metal Mold by Detachment of Resin Mold)

A conductive layer was formed on the columnar pattern-formed surface of the resin mold by sputtering. Then, the resin mold on which the conductive layer had been formed was immersed into a nickel electroforming bath, which contained the following components, for an electroforming treatment. Then, the resin mold was detached from the nickel layer to yield a metal mold 1-2.

(Example of Production of Resin Molded Product with Metal Mold)

The composition-8 was applied onto an easy-adhesion optical PET film substrate (A-4300: 125 μm, manufactured by TOYOBO CO., LTD.) with a bar coater, and the product was heated at 80° C. for 4 minutes. Then, the metal mold 1-2 having the columnar structures arranged into a regular triangular grid and each having a diameter of 230 nm, a height of 200 nm, and a pitch of 460 nm was pressed against the surface of the composition-8. In this state, light was emitted from the coating film side at a light intensity of 300 mJ/cm² with an LED light source (manufactured by IMAC Co., Ltd.) exhibiting the peak wavelength of 375 nm±5 to cure the resin composition-8. Then, the metal mold 1-2 and the PET film substrate were removed to yield a resin molded product 1 having a columnar pattern.

(Components and Temperature of Nickel Electroforming Bath)

Nickel sulfamate . . . 450 g/L

Nickel chloride . . . 5 g/L

Boric acid . . . 40 g/L

Anti-pitting agent . . . 3 g/L

pH adjuster . . . proper quantity

PH=4.0

Temperature=50° C.

### Example 9

As in Example 8, a nanoimprint curable composition-9 (composition-9) used for producing a resin mold was prepared as shown in Table 5.

As in Example 8, a resin mold 2, a metal mold 2-1 produced by alkali solution of the resin mold, a metal mold 2-2 produced by detachment of the resin mold, and a resin molded product 2 were produced.

### Example 10

As in Example 8, a nanoimprint curable composition-10 (composition-10) used for producing a resin mold was prepared as shown in Table 5.

As in Example 8, a resin mold 3, a metal mold 3-1 produced by alkali solution of the resin mold, a metal mold 3-2 produced by detachment of the resin mold, and a resin molded product 3 were produced.

### Example 11

As in Example 8, a nanoimprint curable composition-11 (composition-11) used for producing a resin mold was prepared as shown in Table 5.

As in Example 8, a resin mold 4, a metal mold 4-1 produced by alkali solution of the resin mold, a metal mold 4-2 produced by detachment of the resin mold, and a resin molded product 4 were produced.

### Example 12

As in Example 8, a nanoimprint curable composition-12 (composition-12) used for producing a resin mold was prepared as shown in Table 5.

As in Example 8, a resin mold 5, a metal mold 5-1 produced by alkali solution of the resin mold, a metal mold 5-2 produced by detachment of the resin mold, and a resin molded product 5 were produced.

### Example 13

As in Example 8, a nanoimprint curable composition-13 (composition-13) used for producing a resin mold was prepared as shown in Table 5.

As in Example 8, a resin mold 6, a metal mold 6-1 produced by alkali solution of the resin mold, a metal mold 6-2 produced by detachment of the resin mold, and a resin molded product 6 were produced.

### Example 14

As in Example 8, a nanoimprint curable composition-14 (composition-14) used for producing a resin mold was prepared as shown in Table 5.

As in Example 8, a resin mold 7, a metal mold 7-1 produced by alkali solution of the resin mold, a metal mold 7-2 produced by detachment of the resin mold, and a resin molded product 7 were produced.

### Example 15

As in Example 8, a nanoimprint curable composition-15 (composition-15) used for producing a resin mold was prepared as shown in Table 5.

As in Example 8, a resin mold 8, a metal mold 8-1 produced by alkali solution of the resin mold, a metal mold 8-2 produced by detachment of the resin mold, and a resin molded product 8 were produced.

### Comparative Example 3

As in Example 8, a comparative nanoimprint curable composition (comparative composition-3) used for producing a resin mold was prepared as shown in Table 6.

As in Example 8, a comparative resin mold-1, a comparative metal mold 1-1 produced by alkali solution of the resin mold, a comparative metal mold 1-2 produced by detachment of the resin mold, and a comparative resin molded product 1 were produced.

(Evaluation)

The metal molds and resin molded products produced in Examples 8 to 15 and Comparative Example 3 were evaluated as follows.

(Evaluation of Alkali Solubility of Resin Mold)

In each of Examples, in order to evaluate the release of the resin mold from the metal mold by alkali washing, a rate of a residual resin mold remaining on the release surface of the metal mold was analyzed after the alkali washing; a metal mold exhibiting a rate of the residual resin mold of 0 weight % was evaluated as “Good”, and a metal mold exhibiting a rate of the residual resin mold of greater than 0 weight % was evaluated as “Bad”.

(Evaluation of Detachment of Resin Mold)

In order to evaluate the detachment of the resin mold from the metal mold, a rate of a residual resin mold remaining on the release surface of the metal mold was analyzed; a metal mold exhibiting a rate of the residual resin mold of 0 weight % was evaluated as “Excellent”, a metal mold exhibiting a rate of the residual resin mold of greater than 0 weight % and less than 1 weight % was evaluated as “Good”, a metal mold exhibiting a rate of the residual resin mold of 1 weight % or more and less than 5 weight % was evaluated as “Unacceptable”, and a metal mold exhibiting a rate of the residual resin mold of 5 weight % or more was evaluated as “Bad”.

(Evaluation of Pattern Transfer to Metal Mold)

The pattern transfer to each of the metal molds was analyzed with a scanning microscopy (JSM-7500F manufactured by JEOL Ltd.) at 100,000-folds magnification, and result of the analysis was evaluated as follows.

Good: No damage and deformation were found in the metal mold
Bad: Damage and deformation were found in the metal mold

(Evaluation of Pattern Transfer to Resin Molded Product)

The pattern transfer to each of the resin molded products was analyzed with a scanning microscopy (JSM-7500F manufactured by JEOL Ltd.) at 100,000-folds magnification, and result of the analysis was evaluated as follows.

A: No damage and deformation were found in the metal mold
B: Damage and deformation were found in the metal mold

Tables 5 and 6 show the components of the nanoimprint curable composition used for producing a resin mold and results of the evaluations for the alkali solubility of the resin mold and detachment of the resin mold from the metal mold, the pattern transfer to the metal mold, and the pattern transfer to the resin molded product in each of Examples 8 to 15 and Comparative Example 3.

TABLE 5

| | | Example 8 | Example 9 | Example 10 | Example 11 | Example 12 | Example 13 | Example 14 | Example 15 |
|---|---|---|---|---|---|---|---|---|---|
| Composite resin | A-8 | | | | | 40 | 40 | 40 | |
| | A-9 | | | 40 | | | | | |
| | A-10 | | 40 | | | | | | |
| | A-11 | 40 | | | 40 | | | | 40 |
| (a1) content (%) to composite | | 20 | 75 | 50 | 20 | 50 | 50 | 50 | 20 |
| resin *2 | | | | | | | | | |
| (a1) content (%) *1 | | 11 | 48 | 48 | 5.5 | 35 | 28 | 28 | 5.5 |
| Acid value of composite resin (A) | | 360.4 | 100.2 | 50.2 | 360.4 | 3.9 | 3.9 | 3.9 | 360.4 |
| Polyfunctional | PETA | | 14 | | | 7.4 | 7.4 | 7.4 | |
| acrylate | DPHA | 14.7 | | | 49.5 | | | | 49.5 |
| Urethane acrylate | 17-806 | | | | | | | | |
| Isocyanate | DN-902S | | | | | | 7.4 | 7.4 | |
| compound | | | | | | | | | |
| Photopolymerization | I-184 | 1.39 | 1.7 | 0.88 | 2.78 | 1.1 | 1.1 | 1.1 | 2.78 |
| initiator | | | | | | | | | |
| Mold release agent | BY16-201 | | | | | | | 0.02 | 0.04 |
| UV curable condition [mJ/cm2] | | 300 | 1000 | 1000 | 300 | 1000 | 1000 | 1000 | 300 |
| Nanoimprint curable composition | | Composi- | Composi- | Composi- | Composi- | Composi- | Composi- | Composi- | Composi- |
| | | tion-8 | tion-9 | tion-10 | tion-11 | tion-12 | tion-13 | tion-14 | tion-15 |
| Evaluation | Alkali | Good | Good | Good | Good | Bad | Bad | Bad | Good |
| | solubility of | | | | | | | | |
| | resin mold | | | | | | | | |
| | Detachment | Good | Excellent | Excellent | Unaccept- | Excellent | Excellent | Excellent | Good |
| | of resin | | | | able | | | | |
| | mold | | | | | | | | |
| | Pattern | Good | Good | Good | Good | Good | Good | Good | Good |
| | transfer to | | | | | | | | |
| | metal mold | | | | | | | | |
| | Pattern | Good | Good | Good | Good | Good | Good | Good | Good |
| | transfer to | | | | | | | | |
| | resin | | | | | | | | |
| | molded | | | | | | | | |
| | product | | | | | | | | |

TABLE 6

| | | Comparative |
|---|---|---|
| | | Example 3 |
| Composite resin | A-8 | |
| | A-9 | |
| | A-10 | |
| | A-11 | |
| (a1) content (%) to composite resin *2 | | 0 |
| (a1) content (%) *1 | | 0 |
| Acid value of composite resin (A) | | 0 |
| Polyfunctional | PETA | |
| acrylate | DPHA | |
| Urethane acrylate | 17-806 | 40 |
| Isocyanate compound | DN-902S | |
| Photopolymerization | I-184 | 1.28 |
| initiator | | |
| Mold release agent | BY16-201 | |
| UV curable condition [mJ/cm2] | | 300 |
| Nanoimprint curable composition | | Comparative |
| | | Composition-3 |
| Evaluation | Alkali solubility of resin mold | Bad |
| | Detachment of resin mold | Bad |
| | Pattern transfer to metal mold | Bad |
| | Pattern transfer to resin | Bad |
| | molded product | |

The results of the evaluations in Comparative Example 3 show that the resin mold composition (comparative composition 1) used for producing a metal mold, which contained urethane acrylate, exhibited poor alkali solubility and caused insufficient detachment of the metal mold from the resin molded product.

### Example 16

### Example of Preparation of Wet Etching Resist Film

A nanoimprint curable composition-16 (composition-16) used for forming a wet etching resist film was prepared by mixing 40.0 parts of the composite resin (A-10) synthesized in Synthesis Example 15, 14.7 parts of dipentaerythritol hexaacrylate (DPHA), and 1.39 parts of Irgacure 184 (photopolymerization initiator, manufactured by Ciba Specialty Chemicals Corporation).

(Example of Formation of Uniform Resist Film)

The composition-16 was applied onto a quartz glass substrate with a spin coater, and the product was heated on a hot plate at 80° C. for a minute. Then, light was emitted from the photoresist composition side at a light intensity of 1000 mJ/cm² with an LED light source (manufactured by IMAC Co., Ltd.) exhibiting the peak wavelength of 375 nm±5 to cure a resist film, thereby yielding a wet etching resist film (16-1) having a uniform thickness of 0.5 an on the surface of the substrate.

(Production of Patterned Resist Film)

The composition-16 was, applied onto a quartz glass substrate having a size of 50 mm×50 mm×0.7 mm with a spin coater, and the product was heated on a hot plate at 80° C. for a minute. Then, a planar mold formed of quartz glass and having a structure that was in the form of a line and space with a width of 200 nm, a pitch of 200 nm, and a height of 200 nm was pressed against the surface of the composition-16. In this state, light was emitted from the master mold side at a light intensity of 1000 mJ/cm² with an LED light source (manufactured by IMAC Co., Ltd.) exhibiting the peak wavelength of 375 nm±5 to cure the composition-16. Then, the mold and the quartz glass substrate were removed to yield a wet etching resist film (16-2) having a pattern that was in the form of a line and space.

### Examples 17 and 18 and Comparative Example 4

As in Example 16, a nanoimprint curable composition-17 (composition-17) used for forming a wet etching resist film, a nanoimprint curable composition-18 (composition-18) used for forming a wet etching resist film, and a comparative nanoimprint curable composition-4 (comparative composition-4) were prepared as shown in Table 7.

As in Example 16, a wet etching resist film 17-1, a wet etching resist film 17-2, a wet etching resist film 18-1, a wet etching resist film 18-2, a comparative wet etching resist film H4-1, and a comparative wet etching resist film H4-2 were formed.

(Evaluations of Wet Etching Resist Film)

The wet etching resist films formed in Examples 16 to 18 and Comparative Example 4 were evaluated as follows.

(Evaluation of Wet Etching Resist Film)

<Etching Resistance>

A cylindrical concave-convex structure was formed on a quartz glass substrate as a base plate by wet etching with the wet etching resist film and an etchant that was BHF (buffered hydrogen fluoride), thereby yielding a patterned product that was quartz glass on which a fine structure had been formed. The resist film used for the etching was visually observed and evaluated as follows.

A case in which a resist film did not have problems such as fogging, peeling, and cracking in appearance was evaluated as “Excellent”; a case in which a resist film had, for instance, fine cracks in appearance but a patterned product had no problem in use was evaluated as “Good”; and a case in which a resist film had problems such as peeling and cracking in appearance and the pattern had not been properly transferred to a patterned product was evaluated as “Bad”.

<Alkaline Developability>

To evaluative wet etching resist films, an aqueous solution of 5 wt % hydroxide potassium was sprayed for 60 seconds at a water pressure of 0.2 MPa. A resulting film having a residual ratio of less than 1 weight % was evaluated as “Excellent”, a resulting film having a residual ratio of 1 weight % to 3 weight % was evaluated as “Good”, and a resulting film having a residual ratio of greater than 3 weight % was evaluated as “Bad”.

Table 7 shows the components and results of the evaluations in each Example.

TABLE 7

| | | | | | Comparative |
|---|---|---|---|---|---|
| | | Example 16 | Example 17 | Example 18 | Example 4 |
| Composite resin | A-8 | | | 40 | |
| | A-9 | | 40 | | |
| | A-10 | 40 | | | |
| (a1) content (%) to composite resin *2 | | 75 | 50 | 50 | 0 |
| (a1) content (%) *1 | | 48 | 48 | 35 | 0 |
| Acid value of composite resin (A) | | 100.2 | 50.2 | 3.9 | |
| Polyfunctional | PETA | 14 | | 7.4 | 50 |
| acrylate | DPHA | | | | |
| Urethane acrylate | 17-806 | | | | |
| Isocyanate compound | DN-902S | | | | |
| Photopolymerization initiator | I-0184 | 1.7 | 0.88 | 1.1 | 2 |
| UV curable condition [mJ/cm2] | | 1000 | 1000 | 1000 | 1000 |
| Nanoimprint curable composition | | Composition-16 | Composition-17 | Composition-18 | Comparative |
| | | | | | Composition-4 |
| Evaluation of resist | Etching resistance | Excellent | Excellent | Excellent | Bad |
| film | Alkaline | Excellent | Excellent | Bad | Bad |
| | developability | | | | |

Abbreviations in Table 7
(a1) refers to the polysiloxane segment (a1).
*1 refers to the ratio (%) of the polysiloxane segment (a1) content to the total solid content (including additives) of the curable resin composition.
*2 refers to the ratio (%) of the polysiloxane segment (a1) content to the total solid content of the composite resin (A).
PETA: pentaerythritol triacrylate
DPHA: dipentaerythritol hexaacrylate
DN-902S: BURNOCK 902S (isocyanate compound, manufactured by DIC Corporation)
17-806: BURNOCK 17-806 (urethane acrylate, manufactured by DIC Corporation)
I-184: Irgacure 184

### INDUSTRIAL APPLICABILITY

The nanoimprint-lithographic cured product formed of the nanoimprint curable composition of the present invention and the patterned product, replica mold, and resin molded product each formed of the nanoimprint-lithographic cured product can be used in a variety of applications such as molded films; nano•micro optical elements; optical devices; display devices; electronic paper; storages; packaging materials used for MEMS•PCB; high-performance three-dimensional nano•micro channels used for micro-biochemical analysis, microchemical synthesis, and biochemistry; next-generation electronic devices; and DNA chips.

1. A nanoimprint curable composition comprising a composite resin (A) and a photopolymerization initiator, the composite resin (A) having a polysiloxane segment (a1) and a vinyl polymer segment (a2), the polysiloxane segment (a1) containing a structural unit represented by Formula (1) and/or Formula (2) and a silanol group and/or hydrolyzable silyl group, the polysiloxane segment (a1) and the vinyl polymer segment (a2) being linked to each other through a bond represented by Formula (3) 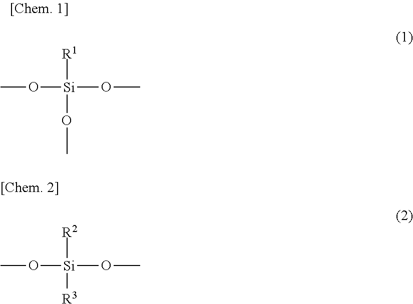
(where R¹, R², and R³ each independently represent a group having a polymerizable double bond which is selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms); an alkyl group having 1 to 6 carbon atoms; a cycloalkyl group having 3 to 8 carbon atoms; an aryl group; or an aralkyl group having 7 to 12 carbon atoms, wherein at least one of R¹, R², and R³ is the group having a polymerizable double bond) 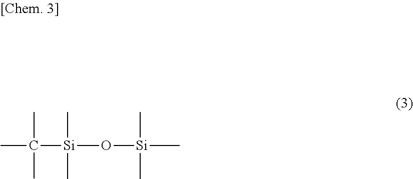
(where the carbon atom constitutes part of the vinyl polymer segment (a2), and the silicon atom bonded to the oxygen atom alone constitutes part of the polysiloxane segment (a1)).

2. The nanoimprint curable composition according to claim 1, wherein the polysiloxane segment (a1) content is from 10 to 90 weight % relative to the composite resin (A).

3. The nanoimprint curable composition according to claim 1, wherein the polymerizable double bond content in the polysiloxane segment (a1) is from 3 to 20 weight %.

4. The nanoimprint curable composition according to claim 1, wherein the group having a polymerizable double bond is a group having a polymerizable double bond which is selected from the group consisting of —R⁴—O—CO—C(CH₃)═CH₂ and —R⁴—O—CO—CH═CH₂ (R⁴ represents a single bond or an alkylene group having 1 to 6 carbon atoms).

5. A nanoimprint-lithographic molded product formed through curing the nanoimprint curable composition according to claim 1.

6. A nanoimprint-lithographic laminate comprising the nanoimprint-lithographic molded product according to claim 5, the nanoimprint-lithographic molded product being formed on a substrate.

7. The nanoimprint-lithographic molded product according to claim 5, wherein the nanoimprint-lithographic molded product is a resist film.

8-11. (canceled)

12. A method for forming a pattern, the method comprising applying the nanoimprint curable composition according to claim 1 to a substrate to form a film; irradiating the nanoimprint curable composition with an active energy ray for curing in a state in which a master mold having a concave-convex structure is pressed against the nanoimprint curable composition; and removing the mold.

13. A method for forming a pattern, the method comprising preparing a resist film that is the nanoimprint-lithographic molded product included in the nanoimprint-lithographic laminate according to claim 6 and dry-etching a substrate through a mask that is a pattern formed in the resist film to form the pattern on the substrate.

14. A method for forming a pattern, the method comprising preparing a resist film that is the nanoimprint-lithographic molded product included in the nanoimprint-lithographic laminate according to claim 6 and wet-etching a substrate through a mask that is a pattern formed in the resist film to form the pattern on the substrate.

15. A patterned product comprising a substrate and a pattern formed on the substrate by the method for forming a pattern according to claims 13.

16-17. (canceled)

18. The nanoimprint curable composition according to claim 2, wherein the polymerizable double bond content in the polysiloxane segment (a1) is from 3 to 20 weight %.

19. The nanoimprint curable composition according to claim 2, wherein the group having a polymerizable double bond is a group having a polymerizable double bond which is selected from the group consisting of —R⁴—O—CO—C(CH₃)═CH₂ and —R⁴—O—CO—CH═CH₂ (R⁴ represents a single bond or an alkylene group having 1 to 6 carbon atoms).

20. The nanoimprint curable composition according to claim 3, wherein the group having a polymerizable double bond is a group having a polymerizable double bond which is selected from the group consisting of —R⁴—O—CO—C(CH₃)═CH₂ and —R⁴—O—CO—CH═CH₂ (R⁴ represents a single bond or an alkylene group having 1 to 6 carbon atoms).

21. A nanoimprint-lithographic molded product formed through curing the nanoimprint curable composition according to claim 2.

22. A nanoimprint-lithographic molded product formed through curing the nanoimprint curable composition according to claim 3.

23. A method for forming a pattern, the method comprising applying the nanoimprint curable composition according to claim 2 to a substrate to form a film; irradiating the nanoimprint curable composition with an active energy ray for curing in a state in which a master mold having a concave-convex structure is pressed against the nanoimprint curable composition; and removing the mold.

24. A method for forming a pattern, the method comprising applying the nanoimprint curable composition according to claim 3 to a substrate to form a film; irradiating the nanoimprint curable composition with an active energy ray for curing in a state in which a master mold having a concave-convex structure is pressed against the nanoimprint curable composition; and removing the mold.

25. A method for forming a pattern, the method comprising applying the nanoimprint curable composition according to claim 4 to a substrate to form a film; irradiating the nanoimprint curable composition with an active energy ray for curing in a state in which a master mold having a concave-convex structure is pressed against the nanoimprint curable composition; and removing the mold.

26. A patterned product comprising a substrate and a pattern formed on the substrate by the method for forming a pattern according to claim 14.
